(19) United States
(12) Patent Application Publication
(10) Pub. No.: US 2007/0137698 A1
(43) Pub. Date: Jun. 21, 2007

(54) Monolithic photovoltaic energy conversion device

(76) Inventors: Mark W Wanlass, Golden, CO (US); Angelo Mascarenhas, Lakewood, CO (US)

Correspondence Address: Paul J. White;Nrel, 1617 Cole Blvd., Golden, CO, 80401, US

(21) Appl. No.: 10/551,598

(22) PCT Filed: Feb. 27, 2002
(86) PCT No.: PCT/US02/05781

§ 371 Date: Sep. 30, 2005

(51) Int. Cl. H01L 31/00

(52) U.S. Cl. 136/261; 136/262

(57) ABSTRACT

A multijunction, monolithic, photovoltaic (PV) cell and device (600) is provided for converting radiant energy to photocurrent and photovoltage with improved efficiency. The PV cell includes an array of subcells (602), i.e., active p/n junctions, grown on a compliant substrate, where the compliant substrate accommodates greater flexibility in matching lattice constants to adjacent semiconductor material. The lattice matched semiconductor materials are selected with appropriate band-gaps to efficiently create photovoltage from a larger portion of the solar spectrum. Subcell strings (601, 603) from multiple PV cells are voltage matched to provide high output PV devices. A light emitting cell and device is also provided having monolithically grown red-yellow and green emission subcells and a mechanically stacked blue emission subcell.

### CONTRACTUAL ORIGIN OF THE INVENTION

The United States Government has rights in this invention under Contract No. DE-AC36-99GO10337 between the United States Department of Energy and the National Renewable Energy Laboratory, a Division of the Midwest Research Institute.

### TECHNICAL FIELD

The present invention relates generally to energy conversion devices, and more particularly to multi-subcell, lattice-matched monolithic photovoltaic cells and light emitting diodes grown on compliant substrates.

### BACKGROUND ART

Solar energy represents a vast source of non-polluting, harnessable energy. It is estimated that the amount of solar energy striking the United States each year far exceeds the country's energy needs for that year. Despite this abundance, solar energy has proven difficult to economically collect, store, and transport, and, thus has been relatively overlooked compared to the other more conventional energy sources, i.e., oil , gas and coal. However, as conventional energy sources become less abundant, and their detrimental effect on the environment continues to escalate (acid rain, air particulates, green house gasses, etc), solar energy is becoming a more viable and attractive energy source.

One of the more effective ways of harnessing solar energy is through photovoltaic (PV) cells, more particularly solar photovoltaic (SPV) cells, which convert solar energy directly into electrical energy. Additionally, there is a second type of PV cell, a thermophotovoltaic (TPV) cell, which converts thermal energy into electrical energy and operates under the same principles as SPV cells. The conversion of radiant energy, e.g., solar and thermal energy, into electrical energy by PV cells relies on p-type and n-type conductivity regions in semiconductor materials. These regions generate a voltage potential and/or current when electron-hole pairs are created in the semiconductor material in response to impinging photons in the PV cell. The amount of energy required to liberate an electron in a semiconductor material is known as the material's band-gap energy. Different PV semiconductor materials have different characteristic band-gap energies. For example, semiconductor materials used in a SPV cell typically have band-gap energies that range from 1.0 eV to 1.6 eV, corresponding to the energy of solar photons, and semiconductor materials in a TPV cell typically have band-gap energies that range from 0.5 eV to 0.75 eV, corresponding to the energy levels of the photons from a thermal source. To maximize the amount of radiant energy absorbed by a PV cell, multi-layered or multi-subcell PV cells have been developed to absorb a wider spectrum of solar or thermal energy.

Multi-subcell PV cells generally include stacks of multiple semiconductor layers or subcells, each subcell composed of a semiconductor material having a band-gap energy designed to convert a different solar/thermal energy level or wavelength range to electricity. The subcell within the PV cell that receives the radiant energy first has the highest band-gap energy, and subcells having correspondingly smaller band-gap energies are ordered/positioned below. Thus, radiant energy in a wavelength not absorbed and converted to electrical energy at the first subcell, having the largest band-gap energy in the PV cell, may be captured and converted to electrical energy at a second subcell, having a band-gap energy smaller than the band-gap energy of the first subcell. In this manner, a broad spectrum of input radiant energy can be converted to electrical energy, providing the PV cell with adequate efficiency for converting input radiant energy into electrical energy.

Although there are multiple ways of fabricating a multi-subcell PV cell, it is preferable to grow the cell as a monolithic crystal. Non-monolithic PV cells require the mechanical alignment and adhesion between different subcells in the cell, a process that is time consuming, costly and can lead to positional errors not evident in monolithic cells. As such, a current goal of the PV field is to fabricate monolithic PV cells.

A limitation in designing multi-junction, monolithic PV cells is the desire for lattice matching between adjacently stacked layers of semiconductor materials that make-up the multi-subcells of the cell. Lattice mismatching between adjacent layers of a PV cell results in strain and dislocations to form, thereby reducing the overall efficiency of the PV cell to convert radiant energy into electrical energy. As such, semiconductor materials used to fabricate monolithic, multi-subcell PV cells will optimally have matched lattice constants. However, there is a limited selection of known semiconductor materials having the requisite band-gap energies for -use in a PV cell, and of these only a few can be lattice matched to form a monolithic PV cell.

Lattice matching limitations between semiconductor materials is further exacerbated by the fact that the subcell semiconductor material is grown on a substrate template, where the substrate has its own, and ultimately limiting, lattice constant that must be matched. As such, the design of monolithic PV cells are typically limited to a set of defined substrate/semiconductor materials having matched lattice constants and appropriate band-gap energy for the intended use (SPV or TPV). Presently, gallium arsenide (GaAs), indium phosphide (anP), and germanium (Ge) are used as templates in growing multi-subcell, monolithic PV cells. Noticeably absent from this list of commonly used substrates in PV cells is silicon. While silicon would be an ideal substrate in terms of durability and expense for use in PV cells, silicon has a lattice constant that is severely incompatible with most direct band-gap semiconductor materials. Note also that silicon, when properly doped to have a junction, has the potential of being a 1.1 eV subcell, ideal for many PV cell applications.

In addition to the lattice matching constraints just described, the design of monolithic, multi-unction PV cells is also constrained by the electric current, and ultimately power which is produced by the PV cell. A PV cell must produce sufficient current and power to make the cell cost effective. Previous attempts to produce adequate photocurrent in PV cells have focused on current matching the series connected subcells within a monolithic, multi-subcell PV cell. Current matching requires that the monolithic, multi-subcell cell be fabricated with subcells IS connected or stacked in series. Unfortunately, current matching limits the cell to the current flow of the smallest current produced by any one of the subcells within the PV subcell stack.

PV cells are typically connected or positioned with respect to one another in a PV device either in strings, stacks, or in combinations of strings and/or stacks. A subcell string typically comprises two or more multi-subcell PV cells arranged side-by-side, inline, in a horizontal string. A subcell string may be composed of a number of individual, discrete PV cells connected together to form the string. Alternatively, a subcell string may be composed of a number of PV cells, each of which is formed on a common substrate (note that the common substrate provides a lattice constant limit on the stacked semiconductor materials). When each of the PV cells having a subcell in a subcell string shares a common substrate, the combination is typically referred to as monolithic interconnected module (MIM).

There is a current need in the art to maximize the output power of these PV devices through the fabrication of more efficient monolithic, multi-subcell PV cells and through novel connections between these PV cells. As such, there is a need in the art for expanding the useful combinations of lattice matched semiconductor materials in a multi-subcell PV cell, as well as a need for fabricating monolithic PV cells and devices with enhanced power outputs.

Against this backdrop the present invention has been developed.

### SUMMARY OF THE INVENTION

The present invention provides monolithic photovoltaic (PV) cells and devices for converting radiant energy to electrical energy, and provides light emitting cells and devices for converting electrical energy into light.

In accordance with an embodiment of the present invention, one or more subcells are fabricated on a silicon based, compliant substrate to provide monolithic PV cells. The compliant substrate flexibly accommodates the lattice constant of target semiconductor materials used in preparing the one or more subcells. Each subcell has a junction of at least one p-type layer of semiconductor material in face-to-face contact with at least one n-type layer of semiconductor material, where each subcell exhibits a predetermined band-gap energy. Monolithic PV cells of the present invention include solar photovoltaic (SPV) cells and thermophotovoltaic (TPV) cells. Semiconductor materials used to fabricate lattice accommodated, one subcell, monolithic SPV cells can include, GaAs, InP, GaAsP₁₋ₓ, and the like. Semiconductor material combinations used to fabricate lattice accommodated, two subcell, monolithic SPV cells include, GaₓIn₁₋ₓPGaAs, GaₓIn₁₋ₓP/GaₓIn₁₋ₓAs, InP/GaₓIn₁₋ₓAs, and the like. Semiconductor material combinations used to fabricate lattice accommodated, three subcell, monolithic SPV cells include, GaₓIn₁₋ₓP/GaAs/Ge, GaₓI₁₋ₓP/GaAs_{y}P_{1-y}/Ge_{z}Si_{1-z}GaₓIn₁₋ₓP/Ga_{y}In_{1-y}As/Ge, and the like. Semiconductor material combinations used to fabricate lattice accommodated, four subcell, monolithic SPV cells include GaₓIn₁₋ₓP/GaAs/Ga_{y}In_{1-y}As_{z}N_{1-z}/Ge, AlₓGa₁₋ₓAs/GaAs/Ga_{y}In_{1-y}As_{z}N_{1-z}Ge, and the like.

The present invention can further be implemented as a monolithic PV device having a plurality of interconnected PV cells, each PV cell having one or more subcells. Subcells within each PV cell are interconnected across the device to form subcell strings, and where the PV cells each have two or more subcells, the PV device can have a multitude of subcell strings. In preferred embodiments, the subcell strings are voltage matched by varying the number of ubcells within a string or by altering the types of connections between subcells in a string, i.e., in series or in parallel.

The present invention can also be implemented as a PV cell having an electrically active silicon layer in the compliant substrate. The silicon layer is processed into silicon subcells, allowing for silicon subcell strings.

In a similar manner, the present invention can be implemented to form light emitting cells and devices.

These and various other features as well as advantages which characterize the present invention will be apparent from a reading of the following detailed description and a review of the associated drawings.

### BRIEF DESCRIPTION OF THE DRAWINGS

FIG. 1 is a graphical representation illustrating the band-gap to lattice constant relationship for expitaxial grown materials for photovoltaic cells and light emitting diodes in accordance with the present invention.

FIG. 2 is a cross-sectional view of an embodiment of a one-band-gap photovoltaic cell in accordance with the present invention.

FIG. 3 is a cross-sectional view of an embodiment of a two-band-gap photovoltaic cell in accordance with the present invention.

FIG. 4 is a cross-sectional view of an embodiment of a three-band-gap photovoltaic cell in accordance with the present invention.

FIG. 5 is a cross-sectional view of an embodiment of a four-band-gap photovoltaic cell in accordance with the present invention.

FIG. 6 is a perspective view of an embodiment of a photovoltaic device having individual photovoltaic cells of the device interconnected in voltage matched strings of subcells in accordance with the present invention.

FIG. 7 is a cross sectional view along line 7-7′ of FIG. 6 to illustrate the interconnection between PV cells, in voltage matching two subcell strings of PV cells.

FIG. 8 is a cross-sectional view of an embodiment of a three-band-gap light emitting cell in accordance with the present invention.

### DETAILED DESCRIPTION

The present invention provides monolithic PV cells having one or more lattice matched subcells on a lattice-accommodating, silicon based, compliant substrate. The present invention also provides PV devices having a plurality of multi-subcell PV cells, and PV devices where the subcells from a plurality of PV cells are connected to form subcell strings that are voltage matched across the device for maximum power output. The invention includes PV devices having electrically active compliant substrates that act as additional subcells in each PV cell. In addition, the present invention provides light emitting cells having a red subcell, green subcell and blue subcell on a lattice-accommodating, silicon based, compliant substrate. Each light emitting device can include a plurality of light emitting cells, where the subcells are connected to form subcell strings and the subeell strings have substantially equal red-yellow, green, and blue voltages that can be independently tuned to adjust the hue of the white light emission.

Monolithic PV Cells

Monolithic PV cells of the present invention convert radiant energy into electrical energy. There are two types of PV cells, SPVs and TPVs, which differ in the target energy level of the photons absorbed and converted into electrical energy. SPV cells are generally designed to convert a portion of solar energy, ranging from higher energy ultraviolet light with wavelengths less than 390 nm to lower energy near-infrared light with wavelengths as long as 2,500 nm, into electrical energy. TPV devices, on the other hand, convert radiant heat, i.e., low energy photons, from low temperature thermal sources (−1,000° C. to 1,500° C.) into electrical energy. Ultimately, it is the band-gap energy of the semiconductor materials used in fabricating a particular PV cell that determines whether the cell is useful as a SPV cell or TPV cell.

Regardless of whether a monolithic PV cell of the present invention is useful as an SPV or TPV device (see below), it will generally include a compliant substrate, one or more subcells composed of p-type and n-type semiconductor material having target band-gap energies, and electrical contacts for transferring energy to and from the cell. Preferably, PV cells of the invention also include one or more passivation/confmement cladding layers (hereinafter “PCC” layers), one or more series connection layers, e.g., tunnel junction, and/or one.or more isolation layers.

In general, the monolithic growth of the above mentioned crystalline semiconductor material attempts to mimic the crystalline structure, i.e., by matching the lattice constant (lattice matched in the context of the present invention refers to the ability of two layers of material being grown as a single crystal, while minimizing the formation of dislocations, strains, or other undesirable defects between the two materials) of the adjacent layer of material. Lattice-matched materials refers to materials with lattice constants that are similar enough that when the two materials are grown adjacent to each other in a single crystal, the difference or mismatch between lattice constants is resolved substantially by elastic deformation and not by inelastic relaxation which often results in the formation of dislocations or other undesirable defects. Within the context of the PV cell art, the combination of materials that make-up an SPV or TPV should be lattice matched and have the appropriate band-gap energies to efficiently function in the conversion of target radiant energy to electrical energy. As such, the growth of a monolithic PV cell requires that the lattice constants of the compliant substrate, subcell materials, and PCC materials be substantially lattice matched.

Compliant substrates of the present invention include a base substrate, an intermediary oxide of the base substrate, and a perovskite oxide deposited thereon. The oxide layer results in interfacial stress relief at the perovskite oxide layer, thereby resulting in the compliant substrate having a ‘flexible’ lattice constant that can accommodate the growth of a wide range of subsequent semiconductor materials. As illustrated in greater detail below, semiconductor materials of the present invention can have lattice constants that vary as much as 8% from the lattice constant of the base substrate in the compliant substrate (see Tables 2-9 below), thereby allowing for a much wider range of potential semiconductor materials to be used in the fabrication of the particular PV cell.

Exemplary perovskite oxide materials in the compliant substrate include strontium titanate (SrTiO₃), barium titanate (BaTiO₃), or mixtures thereof; base substrates for use in the resent invention include silicon, germanium, and/or other Group IV materials, although silicon is the preferred material. Preferred compliant substrate compositions include, but are not limited to, SrTiO₃/ silicon dioxide (SiO₂)/Si, or BaTiO₃/SiO₂/Si.

Base substrates for use in the compliant substrate of the present invention need to be approximately 300 Å thick. Preparation of base substrates in relation to PV cells may be more fully understood with reference to: “Solar Cells: Operating Principles, Technology and System Applications,” Martin Green, Prentice-Hall, N.J. 1982; “Photovoltaic Materials,” Richard Bube, Imperial College Press, 1998. Preparation of compliant substrates for use in accordance with the present invention may be more fully understood with reference to: “Interface Characterization of High Quality Strontium Titanate (SrTiO₃) Films on Silicon (Si) Substrates Grown by Molecular Beam Epitaxy”. J. Ramdani, R. Droopad, et. al., Applied Surface Science, 159-160 (2000) 127-133; “Epitaxial Oxide Thin Films on Silicon”. Z. Tu, J. Ramdani, et al., J. Vac. Sci. Technol. B 18(4), (2000) 2139; “Epitaxial Oxides on Silicon Grown by Molecular Beam Epitaxy”. Ravi Droopad, Zayi Yu, Jamal Ramdani, et al., J. Crystalline Growth 227-228 (2001) 936; and “Plasticity and Inverse Brittle-To-Ductile Transition in Strontium Titonate”. P. Gumbsch, S. Taeri-Baghbadrani, et al., Phys. Rev. Lett. 87 (2001) 085505-1. Each of the above references is incorporated by reference in its entirety.

Semiconductor materials used to fabricate subcells of the present invention are selected based on their intrinsic photocurrent/photovoltage characteristics. Each semiconductor material is chosen for its target band-gap energy based on its lattice matching capability with the compliant substrate, or adjacent semiconductor material. For example TPV cells of the present invention utilize materials having direct band-gap energies of −0.4 eV to 1.1 eV and SPV cells utilize materials having band-gap energies of 0.6 eV to 2.2 eV. In either case the materials must be lattice accommodated or matched to an adjacent material. Note also that growth of a semiconductor material on the perovskite oxide layer requires smooth coverage of the semiconductor material on the perovskite oxide layer. As such, pre-treatment of the perovskite oxide layer with a thin film of surfactant may be required before growth of a target semiconductor material on the perovskite oxide layer.

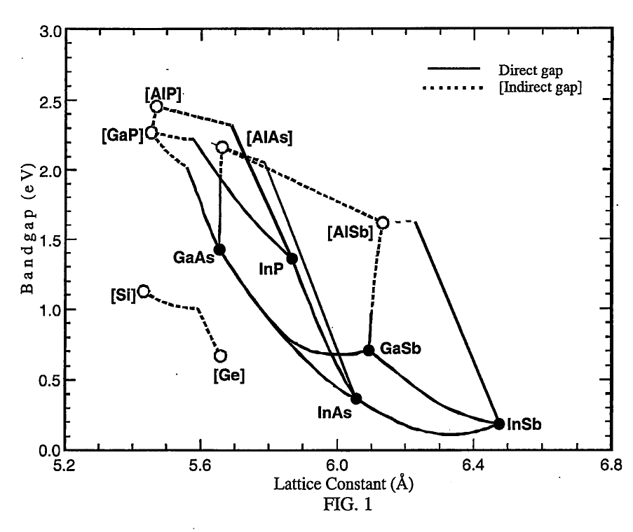

Semiconductor materials for use in the present invention have predictable lattice constant to direct band-gap energy relationships, as shown in FIG. 1. Semiconductor materials having lattice constants that can be accommodated by the compliant substrate include numerous alloys formerly not available for epitaxial growth on, for example, a silicon substrate (see below and Tables 2-9). Note that a materials direct band-gap energy is shown as a solid line, and indirect band-gap energy as a broken line in FIG. 1. As is well known in the art, direct band-gap materials are preferable for use as semiconductor materials in a photovoltaic cell, and except for cells utilizing a bottom Si subcell, are used to fabricate the subcells of the present invention.

The intrinsic properties of a semiconductor material used in a PV cell can be modified through various doping and thickness schemes to achieve desirable carrier movement. Each subcell in a PV cell is composed of an emitter layer of semiconductor material and a base layer of semiconductor material, each layer derived by doping the semiconductor material chosen for that particular subcell, forming a junction within the subcell (such as n/p, p/n, p++/n++ layers). In general, the thickness of the emitter layer is from about 0.01 μm to about 1 μpm, having doping levels of about 10¹⁷ cm⁻³ to about 10²⁰ cm⁻³, and the thickness of the base layer is from about 0.01 μm to about 10 μm, having doping levels of about 10¹⁶ cm⁻³ to about 10¹⁸ cm⁻³. Doping and thickness schemes for semiconductor materials are well known within the art. Note that doping schemes may further be utilized to form interfaces between adjacent layers within a PV cell (see below).

In order.to optimize the use of radiant energy, while simultaneously achieving higher output voltage, the present invention may incorporate a multi-subcell design, i.e., a monolithic PV cell having a compliant substrate and two or more subcells. Multi-subcell PV cells generally have two or more subcells, i.e., energy conversion junctions, each of which is designed to convert a different spectrum of energy or wavelength to electricity, i.e., each subcell has a different band-gap energy. Thus, radiant energy in a wavelength not absorbed by a first subcell having a first band-gap energy may be captured/converted to electrical energy at a second subcell having a second band-gap energy. In general, the subcell having the largest band-gap energy within the PV cell is positioned at the end of the cell directly receiving the input energy, and adjacent subcells having incrementally smaller band-gap energies are stacked sequentially away from the incident energy input.

Table 1 provides illustrative examples of preferred band-gap energies for series connected subcells in a SPV cell, as well as calculated device efficiencies. The table illustrates cells having from one to six subcells. Efficiencies are determined under idealized conditions.

TABLE 1
Optimum Band-gap Energy and Efficiencies for SPVs

| | | |
|---|---|---|
| # of | | |
| Absorber | Efficiency | |
| Cells | (%) | Band-gap Energy (eV) |

| | | | | | | | |
|---|---|---|---|---|---|---|---|
| 1 | 32.4 | 1.4 | | | | | |
| 2 | 44.3 | 1.0 | 1.8 | | | | |
| 3 | 50.3 | 1.0 | 1.6 | 2.2 | | | |
| 4 | 53.9 | 0.8 | 1.4 | 1.8 | 2.2 | | |
| 5 | 56.3 | 0.6 | 1.0 | 1.4 | 1.8 | 2.2 | |
| 6 | 58.5 | 0.6 | 1.0 | 1.4 | 1.8 | 2.0 | 2.2 |

Embodiments of the present invention may further include one or more PCC layers positioned adjacent to the surfaces of a subcell. PCC layers prevent surface or interface recombination within or among a subcell by preventing minority carriers (i.e., orphan carriers) from recombining within the subcell. Recombination of minority carriers at a subcell surface creates losses in photocurrent and photovoltage, thereby reducing the energy conversion efficiency of the PV cell. As such, PCC layers introduce an electronic barrier to minority carriers while acting as an electrical reflector for the subcell. PCC layers are generally composed of low resistivity materials, such as gallium arsenide (GaAs) and are generally from about 0.01 μm to about 0.1 μm in thickness, with doping levels from about 10¹⁶ cm ⁻³ to about 10²⁰cm⁻³. In preferred embodiments, each subcell within a PV cell is bracketed by a pair of PCC layers. Note that where a subcell is not bracketed by a PCC layer it may include a shallow homojunction, as is well known in the art.

Electrical contacts are attached to the PV cells of the present invention for conducting current away from and into the cell. An electrical load can be connected to the cell via grid electrical contacts on top of the cell and ohmic plate contacts at the bottom of the cell to facilitate flow of photocurrent. As may be appreciated, the selection of the direction of conductivity through the PV cell is controlled by the configuration or polarity of the subcell junctions, and the present invention is expressly applicable to current flow in either direction.

The present invention furthe contemplates the positioning of additional materials designed to increase photocurrent and/or photovoltage between adjacent subcells in a PV cell or between subcells of different PV cells. For example, series connection layers, e.g., tunnel junctions, may be provided between subcells of a PV cell to enhance current flow between the subcells of the cell, as is described in greater detail below. Additionally, an alternatively, isolation layers, e.g., high resistivity layers or isolation diodes, may be provided between subcells of a PV cell to limit current flow between the subcells of the cell.

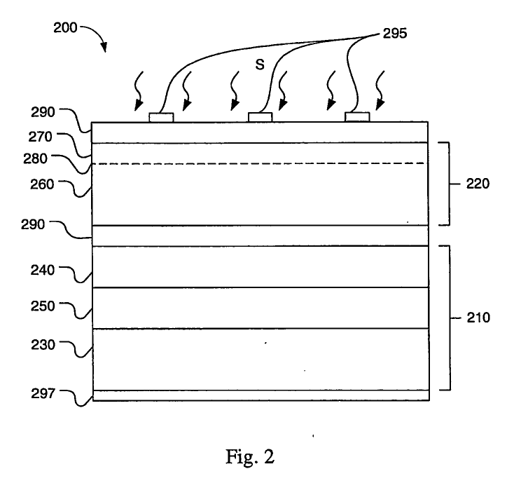

In use, a monolithic PV cell of the present invention has one or more lattice matched, stacked subcells, each subcell having an appropriate band-gap energy, which when struck by photons of appropriate energy convert a portion of the input energy to useable electric energy. In particular, energy absorption and conversion occurs at the one or more subcells, where each subcell is comprised of layers of doped semiconductor materials to form n-type and p-type semiconductor junctions. The present invention contemplates cells having a single subcell with a first band-gap energy, as well as cells having a stack of multiple subcells, with subcells in different layers of the stack having a different band-gap energy for optimum performance, wherein each adjacent subcell is composed of a material lattice matched to the preceding material and thereby optimizing energy conversion efficiencies within the PV cell. Importantly, as discussed above, the first subcell is lattice matched to the flexible lattice constant of the compliant substrate. FIGS. 2-5 provide illustrative diagrams of PV cells in accordance with the present invention, each of which is described in greater detail below.

The PV cell subcells of the present invention may be intraconnected serially with each other via series connection layers or electrically isolated from each other via isolation layers. Note also that subcells in a monolithic PV cell of the present invention can be interconnected, in series or in parallel, to subcells in adjacent PV cells. Subcell strings can be voltage matched to form PV devices, as described in greater detail below.

Serial Connections Within A PV Cell

Stacked subcells in a monolithic, multi-junction PV cell can be current matched to increase photocutrent levels within the cell. In an embodiment of the present invention, PV cells are current matched by stacking in series the subcells, where the current is limited to the smallest current produced by any one of the individual subcells within the PV cell. Current matching can be controlled during fabrication of the PV cell by selecting and controlling the relative band-gap energy of the various semiconductor materials used to form the p-n junctions within each subcell, and/or by altering the thickness of each subcell to modify its resistance. Current flow of each subcell in a PV cell is preferably matched at the maximum power level of the PV cell or at the short-circuit current level of the PV cell, and more preferably at a point between these levels for improved energy conversion efficiency. Current matching of a PV cell is accomplished by inserting a low-resistivity tunnel junction layer between any two current matched subcells to improve current flow. The tunnel junction layer may take a number of forms to provide a thin layer of material that allows current to pass between the subcells, without generating a voltage drop large enough to significantly decrease the conversion efficiency of the PV cell, and that preserves lattice matching between the adjacent subcell semiconductor material. An exemplary tunnel junction layer is a highly doped semiconductor material, such as GaAs. The fabrication and design of tunnel junctions is well known in the art. Note also that other methods of producing series connections for use with the present invention are known in the art and are considered to be within the scope of the present invention.

PV cells of the present invention can be interconnected with each other in various ways, for example, in series connection and parallel connection. In a series connection, each n or p-type conductivity region in a PV cell subcell is connected to an opposite n or p-type region in a second PV cell subcell. Alternatively, in a parallel type electrical connection, each n-type or p-type conductivity region in a PV cell subcell is connected to the same n-type or p-type conductivity region in another PV cell subcell.

Preferred PV cells are described below as one-band-gap, two-band-gap, three-band-gap, and four-band-gap cells. Each PV cell is described in relation to corresponding FIGS. 2-5 and Tables 2-9. Note that Tables 2, 4, 6 and 8 relate to SPV devices and Tables 3, 5, 7 and 9 relate to TPV devices. Also note, the Tables that include PV cells having active compliant substrates silicon), utilizing the MIMs technology, are discussed in greater detail in the following sections.

One Band-gap PV Cells

A one-band-gap PV cell 200 according to the present invention is illustrated in FIG. 2. The cell 200 is a monolithic structure in which each layer of semiconductor material is epitaxially deposited (i.e., grown) to form a single crystal.

The cell 200 includes a compliant substrate 210 and a first subcell 220. A Compliant substrate 210 is generally composed of a base substrate 230 and a perovskite oxide layer 240. A base substrate 230 is, without limitation, a Group IV material, typically silicon (Si). The perovskite oxide layer 240 is usually strontium titanate (SrTiO₃), barium titanate (BaTiO₃), or mixtures thereof (for example SrₓBa₁₌ₓTiO₃, where x can range from 0 to 1). Between the base substrate 230 and perovskite oxide layer 240, an oxide 250 of the substrate material is formed. Thickness of the perovskite oxide layer 240 and oxide 250 may vary but are typically from 120 Å to 160 Å, and from 6 Å to 9 Å, respectively. The lattice constant of the perovskite oxide layer 240 is relaxed as a result of the formed oxide layer 250 which is amorphous (glassy). This yielding of the lattice constant of the perovskite layer allows flexible accommodation for the epitaxial growth of subcell 220, which may include semiconductor materials that were not formally available for growth on silicon or Group IV substrates, i.e., greater selection of semiconductor materials for use in subcell 220 is available within the present invention for epitaxial growth on the compliant substrate 210 (see below in Table 2 and 3). In general, the compliant substrate of the present invention accommodates subcell lattice constants from 5.4 Å to 5.9 Å.

As solar radiation, S, strikes the PV cell 200, the subcell 220 absorbs a portion of the solar radiation, S, and converts the energy in the form of photons to useable electric energy. The subcell 220 comprises a layer of semiconductor materials 260 and 270 doped (e.g., impurities are added that accept or donate electrons) to form appropriate n-type and p-type semiconductor layers. In this manner, a p/n or n/p junction 280 is formed within the subcell 220. Selection of subcell 220 material is in accordance with lattice constants and band-gap as provided by FIG. 1 and may include any semiconductor material or alloy having a lattice constant greater than that of silicon (about 5.4 Å), within lattice matching tolerance afforded by compliant substrate 210 (see Tables 2 and 3 below). Photons having energy, in eV, greater than the designed band-gap of the subcell 220 will be absorbed and converted to electricity across the semiconductor junction 280.

In an alternate embodiment of the present invention the PV cell includes one or more PCC layers 290. PCC layers may be positioned between the compliant substrate 210 and the subcell 220, on top of the subcell, or adjacent to each interface of the subcell (bracketing the subcell layer).

Electrical contacts 297 are attached to the device for conducting current away from and into the PV cell 200. An electrical load (not shown) can be connected to the cell 200 via grid electrical contacts 295 on top of the cell 200 and ohmic plate contact 297 at the bottom of the cell to facilitate flow of photocurrent through the cell 200. The selection of the direction of conductivity through the cell 200 is controlled by the configuration or polarity of the junction 280, and the present invention is expressly applicable to current flow in either direction through the cell 200.

Table 2 shows semiconductor materials available for designing a one band-gap SPV cell, using silicon as a base substrate in the compliant substrate. The table illustrates semiconductor material selection and corresponding band-gap energies and lattice constants for each material. For example, when the semiconductor subcell is GaAs, the-band-gap value is 1.42 eV and lattice constant is 5.65 angstroms (well within the 5.4 Å to 5.9 Å lattice matching available on the compliant substrate). This selection further includes compatible PCC layer(s) for use with each semiconductor material in the PV cell 200. Examples of PCC layers include Al_{y}Ga_{y}In_{1-x-y}As_{z}P₁₋ₓ, and AlₓIn₁₋ₓAs. Doping and thickness schemes for manufacturing devices are well known within the art. In addition and where appropriate, comments regarding each subcell material are discussed, including the use of certain subcell materials mechanically stacked in a PV cell as opposed to monolithically grown.

TABLE 2
One Band-gap Solar Photovoltaic (SPV) Structures

| Subcell | Subcell Band-gap | | |
|---|---|---|---|
| Materials | (E_{g1}) (ₑV) | PCC Materials | Lattice Constant (A)/Comments |
| *GaAs | 1.42 | AlₓGa_{y}In_{1-x-y}As_{z}P_{1-z} | 5.65 |
| *InP | 1.35 | AlₓIn₁₋ₓAs | 5.87 |
| GaAsₓP₁₋ₓ | 1.42-1.6 | AlₓGa_{y}In_{1-x-y}As_{z}P_{1-z} | 5.65-5.6 |
| GaₓIn₁₋ₓP | 1.35-1.6 | AlₓIn₁₋ₓAs or | 5.87-5.75 |
| | | AlₓGa_{y}In_{1-x-y}P | |
| GaₓIn₁₋ₓAs | +01 0.5-1.42 | AlₓGa_{y}In_{1-x-y}As_{z}P_{1-z} | 5.9-5.65/Could be used as a |
| | | | bottom subcell in a mechanically |
| | | | stacked tandem cell (would be |
| | | | grown lattice mismatched on the |
| | | | compliant substrate using a |
| | | | compositionally graded layer). |
| GaAsₓSb₁₋ₓ | 0.75-1.42 | AlₓGa_{y}In_{1-x-y}As_{z}P_{1-z} | 5.9-5.65/Could be used as a |
| | | | bottom subcell in a mechanically |
| | | | stacked tandem cell |
| AlₓIn₁₋ₓAs | 1.35-1.6 | | 5.9-5.8 |
| AlₓGa₁₋ₓAs | 1.42-1.6 | AlₓGa_{y}In_{1-x-y}P | 5.65 |
| AlₓGa_{y}In_{1-x-y}P | 1.35-1.6 | AlₓGa_{y}In_{1-x-y}P | 5.9-5.7 |
| GaₓIn₁₋ₓAs_{y}P_{1-y} | 0.5-1.6 | AlₓGa_{y}In_{1-x-y}As_{z}P_{1-z} | 5.9-5.6/Same comments as for |
| | | | GaₓIn₁₋ₓAs above |
| AlₓGa₁₋ₓAs_{y}Sb_{1-y} | 0.75-1.60 | AlₓGa_{y}In_{1-x-y}As_{z}P_{1-z} | 5.9-5.7/Could be used as bottom |
| | | | subcell in a mechanically stacked |
| | | | tandem cell. |
| AlₓGa_{y}In_{1-x-y}As | 0.6-1.6 | AlₓGa_{y}In_{1-x-y}As_{z}P_{1-z} | 5.9-5.7/Could be used as bottom |
| | | | subcell in a mechanically stacked |
| | | | tandem cell. |
| GeₓSi₁₋ₓ | 0.67-1.1 | | 5.7-5.4/could be used as a bottom |
| | | | subcell in a mechanically stacked |
| | | | tandem cell. |

Within the context of Table 2, * indicates a preferred subcell material, x, y and z have values between 0 and 1 and the sum of any combination of x, y, and z in a subcell or PCC material never exceeds 1.

Table 3 illustrates semiconductor materials available for designing a one band-gap TPV cell, using silicon as the base substrate. The table provides the same type of information as shown in Table 2 above.

TABLE 3
One Band-gap Thermophotovoltaic (TPV) Structures

| Subcell | Subcell Band-gap | | |
|---|---|---|---|
| Materials | (E_{g1}) (eV) | PCC Materials | Lattice Constant (Å)/Comments |
| *Ge | 0.7 | GaₓIn₁₋ₓAs_{y}P_{1-y} | 5.65 |
| *GeₓSi₁₋ₓ | 0.7-1.1 | GaₓIn₁₋ₓAs_{y}P_{1-y} | 5.7-5.4 |
| *GaₓIn₁₋ₓAs | 0.45-1.1 | AlₓGa_{y}In_{1-x-y}As_{z}P_{1-z} | 6.0-5.7/See U.S. Pat. # |
| | | | 6,300,557B1. Band-gaps lower |
| | | | than 0.6 eV are grown LMM on the |
| | | | (Ba)SiTiO₃/SiO₂/Si substrates |
| | | | using an appropriate |
| | | | compositionally graded |
| | | | intermediate buffer region. |
| InAsₓP₁₋ₓ | 0.7-1.1 | AlₓIn₁₋ₓAs | 6.0-5.9/Band-gaps lower than |
| | | | 1.0 eV are grown LMM on the |
| | | | (Ba)SiTiO₃/SiO₂/Si substrates |
| | | | using an appropriate |
| | | | compositionally graded |
| | | | intermediate buffer region. |
| GaAsₓSb₁₋ₓ | 0.7-1.1 | AlₓGa_{y}In_{1-x-y}As_{z}P_{1-z} | 6.0-5.7/Band-gaps lower than |
| | | | 0.8 eV are grown LMM on the |
| | | | (Ba)SrTiO₃/SiO₂/Si substrates |
| | | | using an appropriate |
| | | | compositionally graded |
| | | | intermediate buffer region. |
| *GaₓIn₁₋ₓAs_{y}P_{1-y} | 0.45-1.1 | AlₓGa_{y}In_{1-x-y}As_{z}P_{1-z} | 6.0-5.7/GaₓIn₁₋ₓAs_{y}P_{1-y} alloys |
| | | | with |
| | | | lattice constants larger than 5.9 Å |
| | | | are grown LMM on the |
| | | | (Ba)SrTiO₃/SiO₂/Si substrates |
| | | | using an appropriate |
| | | | compositionally graded |
| | | | intermediate buffer region. |
| *GaₓIn₁₋ₓAs_{y}Sb_{1-y} | 0.5-0.7 | AlₓGa_{y}In_{1-x-y}As_{z}P_{1-z} | 6.0-5.8/GaₓIn₁₋ₓAs_{y}Sb_{1-y} alloys |
| | | | with lattice constants larger than |
| | | | 5.9 Å are grown LMM on the |
| | | | (Ba)SrTiO₃/SiO₂/Si substrates |
| | | | using an appropriate |
| | | | compositionally graded |
| | | | intermediate buffer region. |

Within the context of Table 3, * indicates a preferred subcell material, x, y and z have values between 0 and 1 arnd the sum of any combination of x, y, and z in a subcell or PCC material never exceeds 1. Also note that the term LMM stands for lattice matched monolithically.

Two-Band-gap PV Cells

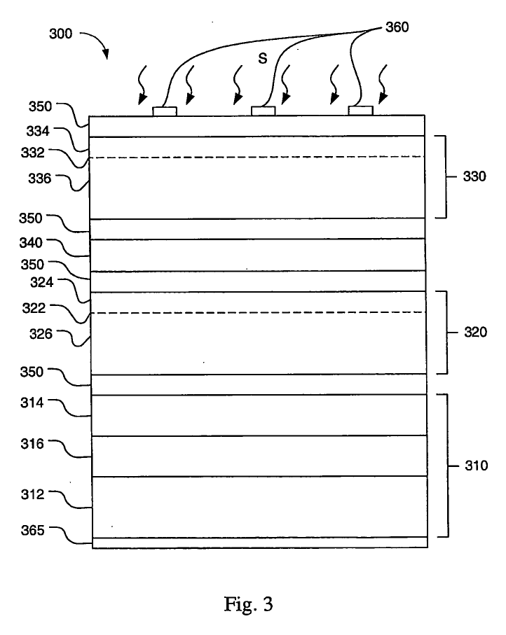

A two-band-gap PV cell is schematically shown in FIG. 3. The two-band-gap cell 300 generally includes a compliant substrate 310, first subcell 320 with junction 322, second subcell 330 with junction 332, and electrical contacts 360 and 365. In addition, preferred embodiments include one or more PCC layers 350 and a tunnel junction 340 for current matched cells.

Similar to the one-band-gap cell 300, the two-band-gap cell is grown monolithically and includes a compliant substrate 310 composed of a base substrate 312, a perovskite oxide layer 314 and intermediary oxide layer 316.

The compliant substrate operates as described above for the one-band-gap cell. As solar radiation, S, strikes the PV cell 300, the first subcell 320 and second subcell 330 each absorb a portion of the solar radiation, S, converting the radiant energy in the form of photons to useable electric energy. The first subcell 320 and second subcell 330 comprise layers of materials 324, 326 and 334, 336 respectively that are doped (e.g., impurities are added that accept or donate electrons) to form n-type and p-type semiconductors. In this manner, the p/n or n/p junctions 322, 332 are formed within subcells 320 and 330. Selection of subcells 320 and 330 in accordance with the lattice constants and band-gaps shown in FIG. 1 may include any semiconductor material or alloy having a lattice constant, within the lattice matching tolerance afforded by the compliant substrate 310. To improve efficient conversion of a fuller range of the input energy spectrum to electricity, it is preferable that the lower subcell 320 have a band-gap that incrementally differs from the band-gap of the top subcell 330, thereby enabling incremental or stepwise absorption of photons of varying energies or wavelengths (see Tables 1, 4 and 5)

As previously stated, alternative embodiments of a two-band-gap device may include one or more PCC layers 350 between and adjacent to subcell materials as described above so as to prevent surface or interface recombination. PCC layers may be positioned between the complaint substrate and the first subcell, between adjacent subcells, or adjacent to each interface of a subcell (bracketing the layer). Pairs of PCC layers are preferably used to bracket the one or more of the subcell layers.

To facilitate photocurrent flow between subcells of the two band-gap PV cell, subcells 320, 330 may include a low-resistivity tunnel junction 340. The tunnel junction 340 may take a number of forms and materials to provide an appropriate layer thickness that allows current to pass between subcells 320, 330 without generating a voltage drop large enough to significantly decrease the conversion efficiency of the cell 300 while preserving lattice-matching between the subcells 320, 330.

It is also envisioned that the layer 340 could be an isolation layer, i.e., independent connections, or layers of electrically insulated material that provide means for extracting individual absorber photovoltage or photocurrent output, rather than a series connection layer, in which case the output of the subcells 320 and 330 would be individually extracted. Alternatively, as discussed below, isolation of the subcells in a PV cell allows for the series or parallel interconnection of subcells between different PV cells.

An electrical load (not shown) can be connected to the PV cell 300 via grid electrical contacts 360 on top of the cell 300 and ohmic plate contact 365 at the bottom of the cell to facilitate flow of photocurrent through the cell 300. In other words, the subcells 320, 330 may be connected in a series circuit. As may be appreciated, the selection of the direction of conductivity through the PV cell 300 is controlled by the configuration or polarity of the absorber junctions 322, 332, and the present invention is expressly applicable to current flow in either direction through the cell 300.

To further facilitate photocurrent flow and conversion efficiency when the two subcells 320, 330 are connected in series, i.e., connected with a tunnel junction or other series connection layer, the first and second subcells 320, 330 may be grown to a predetermined thickness to absorb respective amounts of solar energy, S, thus producing matching amounts of photocurrent across each of the junctions 322, 332. Matched current production is important, in this case, because the subcells 320 and 330 are stacked, connected in series, which means current flow through the PV cell 300 is limited to the smallest current flow in any particular subcell of the device 300. The current flow across each junction 322, 332 is preferably matched in each subcell 320, 330 at the maximum power level of the cell 300 or at the short-circuit current level, and more preferably at a point between these levels for improved solar energy conversion efficiency. Further, the thickness of each subcell in the cell 300 may be selected at the time the cell 300 is fabricated to provide optimized solar energy conversion efficiency for a predetermined application of the cell 300 (terrestrial or space application). For example, the thickness may be increased or decreased at the time of manufacture to produce a cell 300 with high efficiency for use in a device to be used in space, such as a telecommunications satellite. Those persons skilled in the art will further understand that the conversion efficiency of the cell 300 may be optimized through a variety of methods, depending on the semiconductor materials utilized, including selecting the thickness of the layers to control cell voltages and, in special circumstances, to mismatch the photocurrent flow (e.g., have a larger photocurrent flow in the bottom cell).

A significant feature of the present invention is the provision of materials for subcells 320 and 330 that are lattice-matched to the compliant substrate 310. As discussed above, the overall performance of the cell 300 is dependent on lattice-matching of each layer of the cell 300 to the compliant substrate 310 and to intervening layers within the cell as well as to having optimal band-gap energies for a two band-gap cell (see Table 1). The semiconductor materials for use in the first and second subcells of this embodiment are enumerated in Table 4 for an SPV cell and Table 5 for a TPV cell. Reference to the discussion of Table 2 provides a description of each column in Tables 4 and 5.

TABLE 4
Two Band-gap Solar Photovoltaic (SPV) Structures

| Subcell | | | |
|---|---|---|---|
| Materials (L to R, | Subcell Band-gap | | |
| top to bottom | (E_{g2}/E_{g1}) (eV) | PCC Materials | Lattice Const. (A)/Comm. |
| *GaₓIn₁₋ₓP/GaAs | 1.9/1.42 | AlₓGa_{y}In_{1-x-y}As_{z}P_{1-z} | 5.65 |
| AlₓGa₁₋ₓAs/GaAs | 1.9/1.42 | AlₓGa_{y}In_{1-x-y}As_{z}P_{1-z} | 5.65 |
| GaₓIn₁₋ₓP/GaAs_{y}P_{1-y} | 1.9-2.2/1.42-1.9 | AlₓGa_{y}In_{1-x-y}As_{z}P_{1-z} | 5.65-5.55/Could be a top |
| | | | tandem in a mechanically |
| | | | stacked tandem. |
| GaₓIn₁₋ₓP/GaAs_{y}P_{z}N_{1-y-z} | 1.9-2.2/1.0-1.9 | AlₓGa_{y}In_{1-x-y}As_{z}P_{1-z} | 5.65-5.55 |
| GaₓIn₁₋ₓP/GaAs_{y}P_{z}B_{1-y-z} | 1.90-2.2/1.0-1.9 | AlₓGa_{y}In_{1-x-y}As_{z}P_{1-z} | 5.65-5.55 |
| *GaₓIn₁₋ₓP/GaₓIn₁₋ₓAs | 1.35-1.9/0.74-1.42 | AlₓGa_{y}In_{1-x-y}As_{z}P_{1-z} | 5.9-5.65 |
| GaₓIn₁₋ₓP/ | 1.35-2.2/0.74-1.42 | AlₓGa_{y}In_{1-x-y}As_{z}P_{1-z} | 5.9-5.55 |
| Ga_{y}In_{1-y}As_{z}N_{1-z} | | | |
| GaₓIn₁₋ₓP/ | 1.35-2.2/0.74-1.42 | AlₓGa_{y}In_{1-x-y}As_{z}P_{1-z} | 5.9-5.55 |
| Ga_{y}In_{1-y}As_{z}B_{1-z} | | | |
| AlₓGa_{y}In_{1-x-y}P/ | 1.35-2.3/0.74-1.42 | AlₓGa_{y}In_{1-x-y}As_{z}P_{1-z} | 5.9-5.55 |
| GaᵤIn₁₋ᵤAs_{y}N_{1-y} | | | |
| AlₓGa_{y}In_{1-x-y}P/ | 1.35-2.3/0.74-1.42 | AlₓGa_{y}In_{1-x-y}As_{z}P_{1-z} | 5.9-5.55 |
| GaᵤIn₁₋ᵤAs_{y}N_{1-y} | | | |
| *InP/GaₓIn₁₋ₓAs | 1.35/0.74 | AlₓGa_{y}In_{1-x-y}As_{z}P_{1-z} | 5.9 |
| InP/GaAsₓSb₁₋ₓ | 1.35/0.9 | AlₓGa_{y}In_{1-x-y}As_{z}P_{1-z} | 5.9 |
| AlₓIn₁₋ₓAs/GaₓIn₁₋ₓAs | 1.5-2.0/0.74-1.0 | AlₓGa_{y}In_{1-x-y}As_{z}P_{1-z} | 5.9-5.8/ |
| | | | stand-alone tandem or |
| | | | bottom tandem in a |
| | | | mechanically stacked |
| | | | tandem. |
| InAsₓP₁₋ₓ/Ga_{y}IN_{1-y}As | 1.2-1.35/0.65-0.74 | AlₓIn₁₋ₓAs_{z}P_{1-z} | 5.9/A |
| | | | Stand-alone tandem or |
| | | | bottom tandem in a |
| | | | mechanically |
| | | | stacked tandem. |
| *GaₓIn₁₋ₓAs_{y}P_{1-y}/ | 1.2-1.9/0.65-1.42 | AlₓGa_{y}In_{1-x-y}As_{z}P_{1-z} | 5.9-5.65/ |
| GaₓIn₁₋ₓAs | | | A stand-alone tandem or |
| | | | a bottom tandem in a |
| | | | GaₓIn₁₋ₓP/GaAs on |
| | | | Ga_{y}In_{1-y}As_{z}P_{1-z}/GaᵤIn₁₋ᵤAs |
| | | | mechanically stacked, 4 |
| | | | band-gap tandem. |
| GaAsₓP₁₋ₓ/Ge_{y}Si_{1-y} | 1.42-2.0/0.67-1.0 | AlₓGa_{y}In_{1-x-y}As_{z}P_{1-z} | 5.65-5.5 |
| GaAs/Si | 1.42/1.1 | AlₓGa_{y}In_{1-x-y}As_{z}P_{1-z} | 5.65/Active Si subcell. |
| InP/Si | 1.35/1.1 | AlₓIn₁₋ₓAs | 5.87/Active Si subcell. |
| *GaₓIn₁₋ₓP/Si | 1.35-2.2/1.1 | AlₓIn₁₋ₓAs or AlₓGa_{y}In_{1-x-y}P | 5.87-5.55 |
| | | | Active Si subcell. |
| *GaAsₓP₁₋ₓ/Si | 1.42-2.0/1.1 | AlₓGa_{y}In_{1-x-y}As_{z}P_{1-z} | 5.65-5.5 |
| | | | Active Si subcell. |
| AlₓIn₁₋ₓAs/Si | 1.35-2.1/1.1 | | 5.9-5.8 |
| | | | Active Si subcell. |
| AlₓGa₁₋ₓAs/Si | 1.42-1.9/1.1 | AlₓGa_{y}In_{1-x-y}P | 5.65/Active Si subcell. |
| AlₓGa_{y}In_{1-x-y}P/Si | 1.35-2.3/1.1 | AlₓGa_{y}In_{1-x-y}P | 5.9-5.5 Active subcell. |
| *GaₓIn₁₋ₓAs_{y}P_{1-y}/Si | 1.4-1.9/1.1 | AlₓGa_{y}In_{1-x-y}As_{z}P_{1-z} | 5.9-5.6 |
| | | | Active Si subcell. |
| AlₓGa₁₋ₓAs_{y}Sb_{1-y}/Si | 1.4-1.6/1.1 | AlₓGa_{y}In_{1-x-y}As_{z}P_{1=z} | 5.9-5.7 |
| | | | Active Si subcell. |
| AlₓGa_{y}In_{1-x-y}As/Si | 1.4-1.9/1.1 | AlₓGa_{y}In_{1-x-y}As_{z}P_{1-z} | 5.9-5.7 |
| | | | Active Si subcell. |

Within the context of Table 4, * indicates a preferred subcell material, u, v, x, y, and z have values from 0 to 1, and the sum of any combination of u, v, x, y, and z in a subcell or PCC material has a value of from 0 to 1.

TABLE 5
Two Band-gap Thermophotovoltaic (TPV) Structures

| Subcell | | | |
|---|---|---|---|
| Materials (L to R, | Subcell Band-gap | | |
| top to bottom | (E_{g2})(E_{g1}) (eV) | PCC Materials | Lattice Constant (Å)/Comments |
| *GaₓIN₁₋ₓAs/Ga_{y}In_{1-y}As | 1.1-0.5/1.0-0.4 | AlₓGa_{y}In_{1-x-y}As_{z}P_{1-z} | 5.7-6.0/Tandem converter |
| | | | structures are grown LMM on the |
| | | | (Ba)SrTiO₃/SiO₂/Si substrates |
| | | | using appropriate compositionally |
| | | | graded, transparent, intermediate |
| | | | buffer regions. |
| *GaₓIn₁₋ₓAs_{y}P_{1-y}/ | 1.1-0.5/1.0-0.4 | AlₓGa_{y}In_{1-x-y}As_{z}P_{1-z} | 5.7-6.0/Fully lattice matched |
| GaᵤIn₁₋ᵤAsᵥP₁₋ᵥ | | | structures are possible with this |
| | | | system, but band-gaps lower than |
| | | | 0.6 eV would be grown LMM |
| | | | using appropriate compositionally |
| | | | graded, transparent, intermediate |
| | | | buffer regions. |
| *InAsₓP₁₋ₓ/Ga_{y}In_{1-y}As | 1.1-0.6/1.1-0.4 | AlₓGa_{y}In_{1-x-y}As_{z}P_{1-z} | 5.9-6.0/InAsₓP₁₋ₓ/Ga_{y}In_{1-y}As |
| | | | alloys |
| | | | with lattice constants larger than |
| | | | 5.9 Å are grown LMM on the |
| | | | (Ba)SrTiO₃SiO₂/Si substrates |
| | | | using an appropriate |
| | | | compositionally graded, |
| | | | transparent, intermediate buffer |
| | | | region. |
| InAsₓP₁₋ₓ/GaAs_{y}Sb_{1-y} | 1.1-0.6/0.8-0.6 | AlₓGa_{y}In_{1-x-y}As_{z}P_{1-z} | 5.9-6.0/InAsₓP₁₋ₓ/GaAs_{y}Sb_{1-y} |
| | | | alloys with lattice constants larger |
| | | | than 5.9 Å are grown LMM on the |
| | | | (Ba)SrTiO₃/SiO₂/Si substrates |
| | | | using an appropriate |
| | | | compositionally graded, |
| | | | transparent, intermediate buffer |
| | | | region. |
| *InAsₓP₁₋ₓ/ | 1.1-0.6/0.8-0.5 | AlₓGa_{y}In_{1-x-y}As_{z}P_{1-z} | 5.9-6.0/InAsₓP₁₋ₓ/Ga_{y}In_{1-y}As_{z}Sb_{1-z} |
| Ga_{y}In_{1-y}As_{z}P_{1-z} | | | alloys with lattice constants larger |
| | | | than 5.9 Å are grown LMM on the |
| | | | (Ba)SrTiO₃/SiO₂/Si substrates |
| | | | using an appropriate |
| | | | compositionally graded, |
| | | | transparent, intermediate buffer |
| | | | region. |
| *InAsₓP₁₋ₓ | 1.1-0.6/1.1-0.4 | AlₓGa_{y}In_{1-x-y}As_{z}P_{1-z} | 5.9-6.0/InAsₓP₁₋ₓ/Ga_{y}In_{1-y}As_{z}P_{1-z} |
| Ga_{y}In_{1-y}As_{z}P_{1-z} | | | alloys with lattice constants larger |
| | | | than 5.9 Å are grown LMM on the |
| | | | (Ba)SrTiO₃/SiO₂/Si substrates |
| | | | using an appropriate |
| | | | compositionally graded, |
| | | | transparent, intermediate buffer |
| | | | region. |
| *GaₓIn₁₋ₓAs_{y}P_{1-y}/ | 1.1-0.4/1.1-0.4 | AlₓGa_{y}In_{1-x-y}As_{z}P_{1-z} | 5.7-6.0/GaₓIn₁₋ₓAs_{y}P_{1-y}/Ga_{z}In_{1-z}As |
| Ga_{z}In_{1-z}As | | | alloys with lattice constants larger |
| | | | than 5.9 Å are grown LMM on the |
| | | | (Ba)SrTiO₃/SiO₂/Si substrates |
| | | | using an appropriate |
| | | | compositionally graded, |
| | | | transparent, intermediate buffer |
| | | | region. |
| AlₓIn₁₋ₓAs/ | 1.3-0.7/1.1-0.4 | AlₓGa_{y}In_{1-x-y}As_{z}P_{1-z} | 5.9-6.0./AlₓIn₁₋ₓAs/Ga_{y}In_{1-y}As_{z}P_{1-z} |
| Ga_{y}In_{1-y}As_{z}P_{1-z} | | | alloys with lattice constants larger |
| | | | than 5.9 Å are grown LMM on the |
| | | | (Ba)SrTiO₃/SiO₂/Si substrates |
| | | | using an appropriate |
| | | | compositionally graded, |
| | | | transparent, intermediate buffer |
| | | | region. |
| *GaAsₓSb₁₋ₓ/Ga_{y}In_{1-y}As | 1.1-0.6/1.1-0.4 | AlₓGa_{y}In_{1-x-y}As_{z}P_{1-z} | 5.7-6.0/Tandem converter |
| | | | structures are grown LMM on the |
| | | | (Ba)SrTiO₃/SiO₂/Si substrates |
| | | | using appropriate compositionally |
| | | | graded, transparent, intermediate |
| | | | buffer regions. |

Within the context of Table 5, * indicates a preferred subcell material, x, y and z have values between 0 and 1 and the sum of any combination of x, y, and z in a subcell or PCC material never exceeds 1. Also note that the term LMM stands for lattice matched monolithically.

Three-Band-gap PV Cells

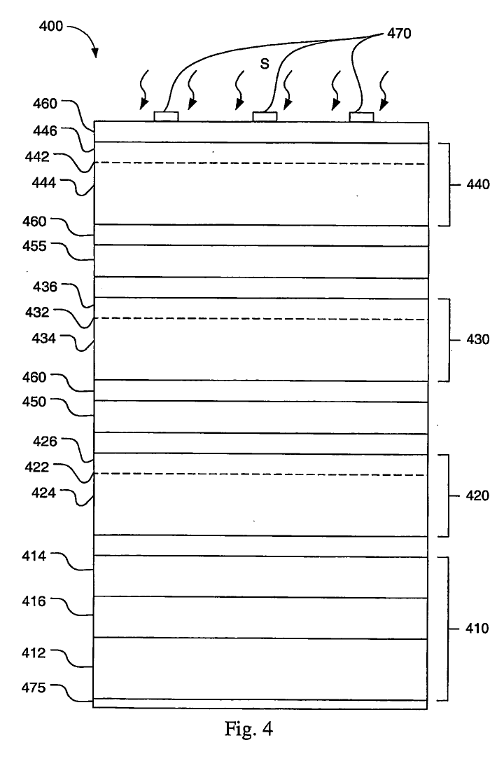

Another embodiment of the present invention is shown in FIG. 4. FIG. 4 schematically represents a three-band-gap PV cell 400, which generally includes a compliant substrate 410, first subcell 420 with junction 422, second subcell 430 with junction 432, third subcell 440 with junction 442, and electrical terminals 470, 475. Preferred embodiments include PCC layers 460 and series connection or isolation layers 450, 455. Note that similar to the one and two band-gap cells 400, the three-band-gap PV cell includes a compliant substrate 410 composed of a base substrate 412, a perovslite oxide layer 414 and intermediary oxide 416 layer.

It should be clear that the use of additional subcells/junctions may improve the efficiency of the PV cell 400 by providing tighter or smaller incremental absorption of the electromagnetic spectrum, S. The components of the PV cell 400 are similar to that of the two-band-gap cell 300, and, as noted above, include a compliant substrate 410, three semiconductor subcells 420, 430, and 440 with active junctions 422, 432, and 442, respectively, comprising doped semiconductor material layers 424, 426, 434, 436, and 444, 446, respectively, layers 450, 455 to facilitate or inhibit photocurrent flow, as the case may be, and front electrical contacts 470 and back contact 475 to apply a load to the cell 400. Subcells 420, 430, and 440 can be current matched by controlling doping levels and growth thickness, with the final thickness depending upon the specific material or alloy selected for each layer. A number of unique embodiments may be created for a three-band-gap cell to meet these requirements and to efficiently absorb an improved portion of the spectrum, S. In one such embodiment of the present invention, the band-gaps of the subcells 420, 430, and 440 are selected such that junctions 442, 432, and 422 are consistent with band-gap energies listed in Table 1. In an alternative embodiment, layers 450 and 455 may be isolation layers so that outputs of subcells 420, 430 and 440 can be individually extracted.

Semiconductor materials for use in the first, second and third subcells for an SPV cell are enumerated in Table 6 and for a TPV cell in Table 7. Reference to Table 2 provides a description of each column.

TABLE 6
Three Band-gap Solar Photovoltaic (SPV) Structures

| Subcell | | | |
|---|---|---|---|
| Materials (L to R, | Subcell Band-gap | | |
| top to bottom | (E_{g3}/E_{g2}/E_{g1}) (eV) | PCC Materials | Lattice Constant (A)/Comments |
| *GaₓIn₁₋ₓP/GaAs/Ge | 1.9/1.4/0.7 | AlₓGa_{y}In_{1-x-y}As_{z}P_{1-z} | 5.65/Bottom subcell is thin |
| | | | epitaxial Ge. |
| *GaₓIn₁₋ₓP/GaₓIn₁₋ₓP/ | 1.9/1.9/1.6-1.7/1.4 | AlₓGa_{y}In_{1-x-y}As_{z}P_{1-z} | 5.65/This design uses two thin |
| Ga_{y}In_{1-y}As_{z}P_{1-z}/GaAs | | | GaₓIn₁₋ₓP upper subcells to split |
| | | | the |
| | | | operating-point current such that |
| | | | the GaₓIn₁₋ₓAs_{y}P_{1-y} subcell can be |
| | | | included in a SC mode. Note 4 |
| | | | active subcell junctions. |
| AlₓIn₁₋ₓP/Ga_{y}In_{1-y}P/ | 1.8-2.3/1.5-1.8/ | AlₓGa_{y}In_{1-x-y}As_{z}P_{1-z} | 5.8-5.9 |
| Ga_{z}In_{1-z}As | 0.7-1.1 | | |
| AlₓGa₁₋ₓAs/GaAs/Ge | 1.7-1.9/1.4/0.7 | AlₓGa_{y}In_{1-x-y}As_{z}P_{1-z} | 5.65/Bottom subcell is thin |
| | | | epitaxial Ge. |
| *GaₓIn₁₋ₓP/GaAs_{y}P_{1-y}/ | 1.9-2.2/1.4-1.9/ | AlₓGa_{y}In_{1-x-y}As_{z}P_{1-z} | 5.65-5.55 |
| Ge_{z}Si_{1-z} | 0.7-1.1 | | |
| GaₓIn₁₋ₓP/GaAs_{y}P_{z}N_{1-y-z}/ | 1.9-2.2/1.4-1.9/ | AlₓGa_{y}In_{1-x-y}As_{z}P_{1-z} | 5.65-5.55 |
| GaᵤIn₁₋ᵤAsᵥN₁₋ᵥ | 1.0-1.4 | | |
| GaₓIn₁₋ₓP/GaAs_{y}P_{z}N_{1-y-z}/ | 1.9-2.2/1.4-1.9/ | AlₓGa_{y}In_{1-x-y}As_{z}P_{1-z} | 5.65-5.55 |
| GaᵤIn₁₋ᵤAs_{y}B_{1-y} | 1.0-1.4 | | |
| GaₓIn₁₋ₓP/GaAs_{y}P_{z}B_{1-y-z/} | 1.9-2.2/1.4-1.9/ | AlₓGa_{y}In_{1-x-y-}As_{z}P_{1-z} | 5.65-5.55 |
| GaᵤIn₁₋ᵤAsᵥN₁₋ᵥ | 1.0-1.4 | | |
| GaₓIn₁₋ₓP/GaAs_{y}P_{z}B_{1-y-z}/ | 1.9-2.2/1.0-1.9/ | AlₓGa_{y}In_{1-x-y}As_{z}P_{1-z} | 5.65-5.55 |
| GaᵤIn₁₋ᵤAsᵥB₁₋ᵥ | 1.0-1.4 | | |
| *GaₓIn₁₋ₓP/Ga_{y}In_{1-y}As/Ge | 1.35-1.9/0.7-1.4/0.7 | AlₓGa_{y}In_{1-x-y}As_{z}P_{1-z} | 5.9-5.65/“Metamorphic” |
| | | | GaₓIn₁₋ₓP/GaₓIn₁₋ₓAs |
| | | | subcells grown on a |
| | | | transparent compositionally |
| | | | graded layer. |
| AlₓGa_{y}In_{1-x-y}P/ | 1.35-2.3/0.7-1.4/ | AlₓGa_{y}In_{1-x-y-}As_{z}P_{1-z} | 5.9-5.55 |
| Ga_{w}In_{1-w}As_{z}P_{1-z}/ | 0.5-1.4 | | |
| GaᵤIn₁₋ᵤAsᵥN₁₋ᵥ | | | |
| AlₓGa_{y}In_{1-x-y}P/ | 1.35-2.3/0.7-1.4/ | AlₓGa_{y}In_{1-x-y}As_{z}P_{1-z} | 5.9-5.55 |
| Ga_{w}In_{1-w}As_{z}P_{1-z}/ | 0.5-1.4 | | |
| GaᵤIn₁₋ᵤAsvB₁₋ᵥ | | | |
| AlₓGa_{y}In_{1-x-y}P/ | 1.9-2.3/1.4-1.9/ | AlₓGa_{y}In_{1-x-y}As_{z}P_{1-z} | 5.65-5.5 |
| GaAs_{z}P_{1-z}/GeᵤSi₁₋ᵤ | | | |
| AlₓGa_{y}In_{1-x-y}P/ | 1.4-2.3/1.4-1.9/ | AlₓGa_{y}In_{1-x-y}As_{z}P_{1-z} | 5.65-5.5 |
| GaᵤIn₁₋ᵤAsᵥP₁₋ᵥGe_{z}Si_{1-z} | 0.7-1.1 | | |
| *GaₓIn₁₋ₓP/GaAs/Si | 1.9/1.4/1.1 | AlₓGa_{y}In_{1-x-y}As_{z}P_{1-z} | 5.65/Active Si subcell |
| *GaₓIn₁₋ₓP/GaAsᵥP₁₋ᵥ/Si | 1.9-2.2/1.4-1.9/1.1 | AlₓGa_{y}In_{1-x-y}As_{z}P_{1-z} | 5.65-5.5/Active Si subcell |
| GaₓIn₁₋ₓP/GaAs_{y}P_{z}N_{1-y-z}/ | 1.9-2.2/1.4-1.9/1.1 | AlₓGa_{y}In_{1-x-y}As_{z}P_{1-z} | 5.65-5.5/Active Si subcell |
| Si | | | |
| AlₓIn₁₋ₓP/GaₓIn₁₋ₓP/Si | 1.35-2.3/1.35-1.7/1.1 | AlₓGa_{y}In_{1-x-y}As_{z}P_{1-z} | 5.9-5.7/Active Si subcell |
| AlₓGa₁₋ₓAs/GaAs/Si | 1.4-1.9/1.4/1.1 | AlₓGa_{y}In_{1-x-y}P | 5.65/Active Si subcell |
| AlₓGa_{y}In_{1-x-y}P/ | 1.35-2.3/1.2-2.1/1.1 | AlₓGa_{y}In_{1-x-y}As_{z}P_{1-z} | 5.9-5.5/Active Si subcell |
| Ga_{w}In_{1-w}As_{z}P_{1-z}/Si | | | |
| AlₓGa_{y}In_{1-x-y}As/ | 1.4-1.9/1.2-1.7/1.1 | AlₓGa_{y}In_{1-x-y}As_{z}P_{1-z} | 5.9-5.7/Active Si subcell |
| Ga_{w}In_{1-w}As_{z}P_{1-z}/Si | | | |

Within the context of Table 6, * indicates a preferred subcefl material, u, v, W, x, y, and z have values from 0 to 1, and the sum of any combination of u, v, w, x, y, and z in a subcell or PCC material has a value of from 0 to 1.

TABLE 7
Three Band-gap Thermophotovoltaic (TPV) Structures

| Subcell | | | |
|---|---|---|---|
| Materials (L to R, | Subcell Band-gap | | |
| top to bottom | (E_{g3})(E_{g2})(E_{g1}) (eV) | PCC Materials | Lattice Constant (Å)/Comments |
| *GaₓIn₁₋ₓAs/Ga_{y}In_{1-y}As | 1.1-0.4/1.0-0.4/ | AlₓGa_{y}In_{1-x-y}As_{z}P_{1-z} | 5.7-6.0/GaAsₓSb₁₋ₓ could be |
| Ga_{z}In_{1-z}As | 0.9-0.4 | | substituted for any of the Ga_{y}In_{1-y} |
| | | | As subcells for band-gaps as low |
| | | | as 0.7 eV. These are LMM |
| | | | structures that utilize appropriate |
| | | | compositionally graded, |
| | | | transparent, intermediate buffer |
| | | | regions between the subcells. |
| *GaₓIn₁₋ₓAs_{y}P_{1-y}/ | 1.1-0.4/1.0-0.4/ | AlₓGa_{y}In_{1-x-y}As_{z}P_{1-z} | 5.7-6.0/Fully lattice matched |
| GaᵤIn₁₋ᵤAsᵥP₁₋ᵥ/ | 0.9-0.4 | | tandem structures are possible with |
| Ga_{w}In_{1-w}As_{z}P_{1-z} | | | this system. Band-gaps less than |
| | | | 0.6 eV require LMM. |
| AlₓIn₁₋ₓAs/InAs_{y}P_{1-y}/ | 1.3-0.7/1.1-0.6/ | AlₓGa_{y}In_{1-x-y}As_{z}P_{1-z} | 5.9-6.0/Fully lattice matched |
| GaᵤIn₁₋ᵤAsᵥP₁₋ᵥ | 1.0-0.4 | | tandem structures are possible with |
| | | | this system. The lowest band-gaps |
| | | | require LMM. |
| AlₓIn₁₋ₓAs/InAs_{y}P_{1-y}/ | 1.3-0.7/1.1-0.6/ | AlₓGa_{y}In_{1-x-y}As_{z}P_{1-z} | 5.9-6.0/Fully lattice matched |
| GaₓIn₁₋ₓAs_{y}Sb_{1-y} | 1.0-0.4 | | tandem structures are possible with |
| | | | this system. The lowest band-gaps |
| | | | require LMM. |

Within the context of Table 7, * indicates a preferred subcell material, u, V, W, x, y, and z have values from 0 to 1, and the sum of any combination of u, v, w, x, y, and z in a subcell or PCC material has a value of from 0 to 1.

Four-Band-gap PV Cells

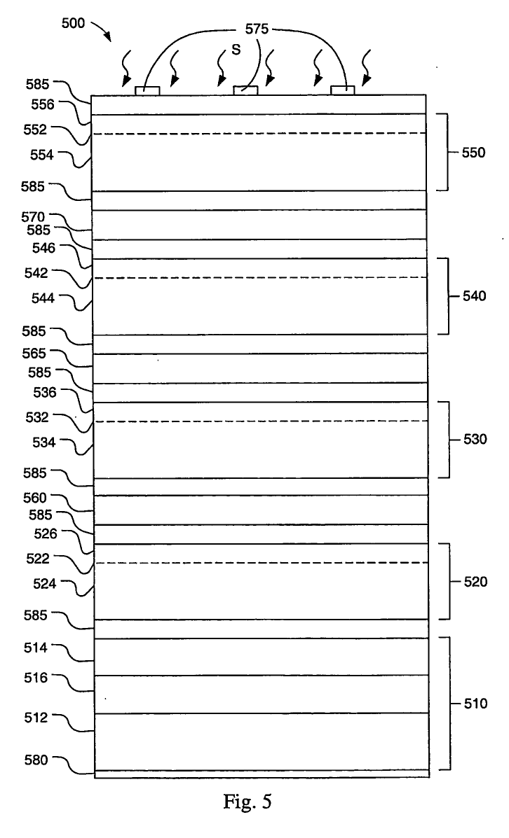

Another embodiment of the present invention is shown in FIG. 5. FIG. 5 schematically illustrates a four-band-gap PV cell 500, which absorbs radiant energy in four increments. A variety of semiconductor materials and base substrate material may be utilized to fabricate the cell 500 with the added (fourth) subcell/junction being selected to have a band-gap that better facilitates absorption of the input energy spectrum (see Table 1). For example, PV cell 500 may be designed with a junction having a band-gap energy lower, intermediate, or higher than in a three-band-gap cell to improve the energy conversion of a three-band-gap cell.

As illustrated by FIG. 5, in one embodiment the cell 500 includes a compliant substrate 510, semiconductor subcells 520, 530, 540, and 550 with junctions 522, 532, 542, and 552, respectively, comprising selectively doped semiconductor material layers 524, 526, 534, 536, 544, 546, and 554, 556, respectively, series connection layers 560, 565, and 570 (or isolation layers), PCC layers 585, and grid electrical contacts 575 and ohmic contact 580 for applying a load (not shown) to the cell 500. The illustrated cell 500 combines a new, bottom, fourth subcell 520 with junction 522, with the subcells 530,540 and 550 similar to that of the three-band-gap cell discussed above. In this regard, subcells 530, 540, and 550 of PV cell 500 may correspond to the materials in a three-band-gap embodiment of the present invention. With the addition of subcell 520 with junction 522, the device 500 advantageously absorbs photons with energy ranging from 0.67 eV to about 1 eV which were not absorbed in the second embodiment discussed above. Note as above, layers 560, 565 and 570 may be isolation layers so that outputs of subcells 520, 530, 540 and 550 can be individually extracted. Semiconductor materials for use in the first; second, third and fourth subcells for an SPV cell are enumerated in Table 8 and a TPV cell in Table 9. Reference to Table 2 provides description of each column.

TABLE 8
Four Band-gap Solar Photovoltaic (SPV) Structures

| Subcell | Subcell Band-gap | | |
|---|---|---|---|
| Materials (L to R, | (E_{g4}/E_{g3}/E_{g2})(E_{g1}) | | |
| top to bottom | (eV) | PCC Materials | Lattice Constant (Å)/Comments |
| *GaₓIn₁₋ₓP/GaAs/ | 1.9/1.4/0.9-1.1/0.7 | AlₓGa_{y}In_{1-x-y-}As_{z}P_{1-z} | 5.65/bottom subcell is a thin |
| Ga_{y}In_{1-y}As_{z}N_{1-z}/Ge | | | epitaxial Ge |
| GaₓIn₁₋ₓP/GaAs/ | 1.9/1.4/0.9-1.1/.07 | AlₓGa_{y}In_{1-x-y}As_{z}P_{1-z} | 5.65./Bottom subcell is a thin |
| GaᵤIn₁₋ᵤAsᵥB₁₋ᵥ/Ge | | | epitaxial Ge. |
| *GaₓIn₁₋ₓP/GaₓIn₁₋ₓP/ | 1.9/1.9/1.6-1.7/1.4/ | AlₓGa_{y}In_{1-x-y}As_{z}P_{1-z} | 5.65/This design uses two thin |
| GaᵤIn₁₋ᵤAsᵥP₁₋ᵥ/GaAs/ | 0.9-1.1 | | GaₓIn₁₋ₓP upper subcells to split |
| GaᵥIn_{1-y}As_{z}N_{1-z} | | | the |
| | | | operating-point current such that |
| | | | the GaᵤIn₁₋ᵤAsᵥP₁₋ᵥ subcell can be |
| | | | included in a SC mode. Note 5 |
| | | | active subcell junctions. |
| GaₓIn₁₋ₓP/GaₓIn₁₋ₓP/ | 1.9/1.9/1.6-1.7/1.4/ | AlₓGa_{y}In_{1-x-y}As_{z}P_{1-z} | 5.65/This design uses two thin |
| Ga_{y}In_{1-y}As_{z}P_{1-z}GaAs/ | 0.9-1.1 | | GaₓIn₁₋ₓP upper subcells to split |
| GaᵤIn₁₋ᵤAsᵥB₁₋ᵥ | | | the |
| | | | operating point current such that |
| | | | the Ga_{y}In_{1-y}As_{z}P_{1-z} subcell can be |
| | | | included in a SC mode. Note 5 |
| | | | active subcell junctions. |
| *GaₓIn_{1-z}P/GaₓIn₁₋ₓP/ | 1.9/1.9/1.6-1.7/1.4/1.1 | AlₓGa_{y}In_{1-x-y}As_{z}P_{1-z} | 5.65/This design uses two thin |
| GaᵤIn₁₋ᵤAsᵥP₁₋ᵥ/GaAs/Si | | | GaₓIn₁₋ₓP upper subcells to split |
| | | | the |
| | | | operating point current such that |
| | | | the GaᵤIn₁₋ᵤAsᵥP₁₋ᵥ subcell can be |
| | | | included in a SC mode. |
| GaₓIn₁₋ₓP/GaₓIn₁₋ₓP/ | 1.9/1.9/1.6-1.7/1.4/0.7 | AlₓGa_{y}In_{1-x-y}As_{z}P_{1-z} | 5.65/This design uses two thin |
| GaᵤIn₁₋ᵤAsᵥP₁₋ᵥ/GaAs/Ge | | | GaₓIn₁₋ₓP upper subcells to split |
| | | | the |
| | | | operating point current such that |
| | | | the GaᵤIn₁₋ᵤAsᵥP₁₋ᵥ subcell can be |
| | | | included in a SC mode. Note 5 |
| | | | active subcell junctions. Also uses |
| | | | a thin epitaxial Ge subcell. |
| AiₓGa₁₋ₓAs/GaAs/ | 1.9/1.4/0.9-1.1/0.7 | AlₓGa_{y}In_{1-x-y}As_{z}P_{1-z} | 5.65/Bottom subcell is thin |
| Ga_{y}In_{1-y}As_{z}N_{1-z}/Ge | | | epitaxial Ge |
| AlₓGa₁₋ₓAs/GaAs/ | 1.9/1.4/0.9-1.1/0.7 | AlₓGa_{y}In_{1-x-y}As_{z}P_{1-z} | 5.65/Bottom subcell is thin |
| GaᵤIn₁₋ᵤAsᵥB₁₋ᵥ/Ge | | | epitaxial Ge |
| AlₓGa₁₋ₓAs/AlₓGa₁₋ₓAs/ | 1.9/1.9/1.6-1.7/1.4/ | AlₓGa_{y}In_{1-x-y}As_{z}P_{1-z} | 5.65/This design uses two thin |
| GaᵤIn₁₋ᵤAsᵥP₁₋ᵥ/GaAs/ | 0.9-1.1 | | AlₓGa₁₋ₓAs upper subcells to split |
| Ga_{y}In_{1-y}As_{z}N_{1-z} | | | the operating point current such |
| | | | that the GaᵤIn₁₋ᵤAsᵥP₁₋ᵥ subcell can |
| | | | be included in a SC mode. Note 5 |
| | | | active subcell junctions. |
| AiₓGa₁₋ₓAs/AlₓGa₁₋ₓAs/ | 1.9/1.9/1.6-1.7/1.4/ | AlₓGa_{y}In_{1-x-y}As_{z}P_{1-z} | 5.65/This design uses two thin |
| Ga_{y}In_{1-y}As_{z}P_{1-z}/GaAs/ | 0.9-1.1 | | AlₓGa₁₋ₓAs upper subcells to split |
| GaᵤIn₁₋ᵤAsᵥB₁₋ᵥ | | | the operating point current such |
| | | | that Ga_{y}In_{1-y}As_{z}P_{1-z} subcell can be |
| | | | included in a SC mode. Note 5 |
| | | | active subcell junctions |
| AlₓGa₁₋ₓAs/AlₓGa₁₋ₓAs/ | 1.9/1.9/1.6-1.7/1.4/1.1 | AlₓGa_{y}In_{1-x-y}As_{z}P_{1-z} | 5.65/This design uses two thin |
| Ga_{y}In_{1-y}As_{z}P_{1-z}/GaAs/Si | | | AlₓGa₁₋ₓAs upper subcells to split |
| | | | the operating point current such |
| | | | that the Ga_{y}In_{1-y}As_{z}P_{1-z} subcell can |
| | | | be included in a SC mode. |
| | | | Note 5 active subcell junctions. |
| | | | Also uses an active Si subcell. |

Within the context of Table 8, * indicates a preferred subcell material, U, v, x, y, and z have values from 0 to 1, and the sum of any combination of u, v, x, y, and z in a subcell or PCC material has a value of from 0 to 1.

TABLE 9
Four Band-gaps Thermophotovoltaic (TPV) Structures

| Subcell | | | |
|---|---|---|---|
| Materials (L to R, | Subcell Band-gap | | |
| top to bottom | (E_{g4})(E_{g3})(E_{g2})(E_{g1}) (eV) | PCC Materials | Lattice Constant (Å)/Comments |
| *GaₓIn₁₋ₓAs/Ga_{y}In_{1-y}As/ | 1.1-0.4/1.0-0.4/ | AlₓGa_{y}In_{1-x-y}As_{z}P_{1-z} | 5.7-6.0/GaAsₓSb₁₋ₓ could be |
| Ga_{z}In_{1-z}As/GaᵤIn₁₋ᵤAs | 0.9-0.4/0.8-0.4 | | substituted for any of the Ga_{y}In_{1-y} |
| | | | As subcells for band-gaps as low |
| | | | as 0.7 eV. These are LMM |
| | | | structures that utilize appropriate |
| | | | compositionally graded, |
| | | | transparent, intermediate buffer |
| | | | regions between the subcells. |
| *GaₓIn₁₋ₓAs_{y}P_{1-y}/ | 1.1-0.4/1.0-0.4/ | AlₓGa_{y}In_{1-x-y}As_{z}P_{1-z} | 5.7-6.0/Fully lattice matched |
| Ga_{y}In₁₋ᵥAsᵤP₁₋ᵤ/ | 0.9-0.4/0.8-0.4 | | tandem structures are possible with |
| Ga_{w}In_{1-w}As_{z}P_{1-z}/ | | | this system. Band-gaps less than |
| GaₛIn₁₋ₛAsₜP₁₋ₜ | | | 0.6 eV require LMM. |
| AlₓIn₁₋ₓAs/InAs_{y}P_{1-y}/ | 1.3-0.7/1.1-0.6/ | AlₓGa_{y}In_{1-x-y}As_{z}P_{1-z} | 5.9-6.0/Fully lattice matched |
| Ga_{z}In_{1-z}AsᵤP₁₋ᵤ/ | 1.0-0.4/0.9-0.4 | | tandem structures are possible with |
| GaᵥIn₁₋ᵥAs_{w}Sb_{1-w}/ | | | this system. The lowest band-gaps |
| | | | require LMM. |

Within the context of Table 9, u, v, w, x, y, and z have values from 0 to 1, and the sum of any combination of u, v, w, x, y, and z in a subcell or PCC material has a value of from 0 to 1.

Note also that the following references provide additional detail regarding SPV and TPV subcell material options, each of which is incorporated by reference herein in its entirety: “Single-Junction Solar Cells with the Optimum Band Gap for Terrestrial Concentrator Applications,” M. W. Wanlass, U.S. Pat. No. 5,376,185; “Monolithic Tandem Solar Cell,” M. W. Wanlass, U.S. Pat. No. 5,322,572; “Monolithic Tandem Solar Cell,” M. W. Wanlass, U.S. Pat. No. 5,019,177; “Multi-Junction, Monolithic Solar Cell Using Low-Band-Gap Materials Lattice Matched to GaAs or Ge,” Olson et al., U.S. Pat. No. 6,281,426B1; “High-efficiency Solar Cell Using and Method of Fabrication,” Hou et al., U.S. Pat. No. 5,944,913; “Isoelectronic Co-doping,” A. Mascarenhas, U.S. patent application Ser. No. 09/841,691.

Voltage Matched, Monolithic, Multi-Jwuction PV Devices

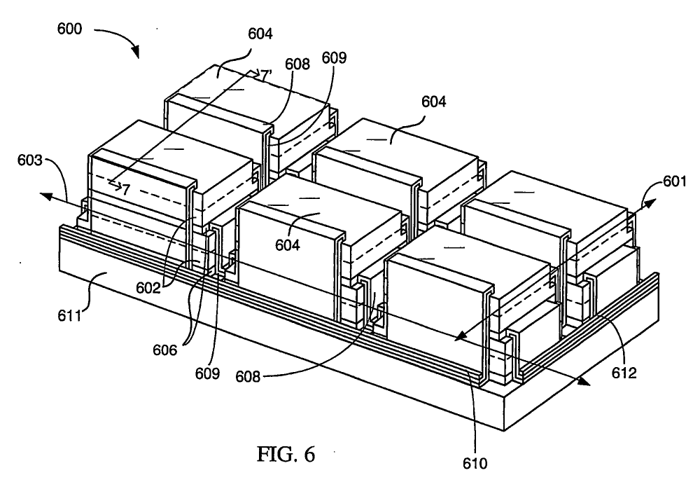

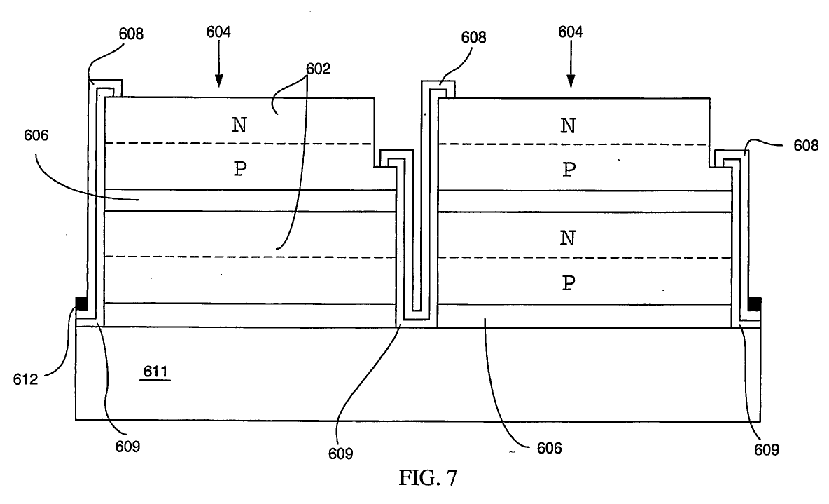

In another embodiment of the present invention, subcells in one PV cell are voltage-matched to subcells in a different PV cell to form voltage-matched, monolithic, tandem bi-junction and/or two-subcell (BT-MIM) PV devices. Voltage matching of two separate subcell strings is accomplished through a biaxial interconnection scheme that takes advantage of the two degrees of freedom available on a planar surface to make two independent, orthogonal, serially interconnected subcell strings (see FIGS. 6 and 7). As illustrated in FIGS. 6 and 7, subcells in a subcell string (indicated by lines 601 and 603) in a voltage matched PV device 600 are simultaneously electrically isolated from the other subcells 602 within the PV cell 604, by an isolation layer 606 of material, i.e., isolating diode, plurality of isolating diodes, oxide layers, etc, and serially interconnected to an appropriate subcell along the string by metallic interconnections 608. Subcells 602 are selected and grown as discussed above on a compliant substrate 609. PCC layers (not shown) may be included in PV cells of voltage matched devices as discussed above.

Voltage matching the subcell strings is achieved by adjusting the number of interconnected subcells 602 in each of the subcell strings 601 and 603, such that the product of the number of subcells times the maximum-power-point voltage per subcell is equivalent for. both subcell strings, i.e., serially interconnected subcell strings are voltage matched if nVₘₚ(low band-gap)=mVₘₚ(high band-gap). As such, the two subcell strings 601 and 603 from the different PV cells can be connected in parallel on the edge of the MIM to form a two-terminal 610 and 612 PV device or module. The output power of the tandem MIM PV device is then the sum of the subcell currents multiplied by the matched voltage generated by each of the subcell strings, i.e., Power=[Jₘₚ(high band-gap)+Jₘₚ(low band-gap)] [n or m]Vₘₚ(high band-gap or low band-gap). The geometric design of the subcell mesa in the BT-MM depends on the target band-gap energy of the semiconductor material and on the application required. To affect voltage matching, n is always less than m, which means that the dimension of the mesa along the high band-gap subcell string will be longer than the other dimension.

Embodiments of the present invention include two-terminal PV devices having two voltage matched strings of subcells, monolithically grown on a compliant substrate. Semiconductor materials used for the subcells of the voltage matched PV devices are shown above in Tables 4 and 5. As discussed above, stacked subcells in a PV cell must be electrically insulated from each other using electrically insulating material. For example, layers 350 (FIG. 3), 450 and 455 (FIG. 4) and 560, 565 and 570 (FIG. 5) would all be composed of a material (having high resistivity) to electrically isolate any adjacent subcell.

In a related embodiment, the silicon layer of the compliant substrate is appropriately doped to have a p-typeln-type junction. The silicon layer is electrically “activated” prior to the growth of the perovskite oxide layer on the silicon layer to incorporate a Si subcell. Note also that the electrically active silicon has a band-gap energy of approximately 1.1 eV, ideal for many SPV cell applications. Voltage matching of Si subcell string(s) with subcell strings in the subsequently grown absorbing layers comprising the bi-junction device is achieved as discussed earlier for BT-MIM devices. Note that the doped silicon layer of the compliant substrate is electrically isolated from the stacked subcells via the compliant substrate layer's dioxide layer. However, if necessary, an isolation layer can be inserted. Tables 4 and 5 provide possible semiconductor material/active silicon combinations for use in the present invention. So for example, as shown in Table 4, GaAs composed subcells are interconnected to form a first subcell string and silicon subcells are interconnected to form a second subcell string. Formation of the doped silicon base layer into discrete subcell units requires that the substrate be etched and may require a glass or glass-like template as a template for growth of the compliant substrate (thereby electrically isolating each silicon subcell from any other silicon subcell).

A fuller explanation of BT-MLMs is provided in the co-pending application entitled “Voltage-Matched, Monolithic Tandem, Multi-Band-Gap Devices,” having the same inventive and ownership entities, and having been filed on the same day as the present application, which is incorporated herein by reference in its entirety.

An alternative embodiment of the present invention is a monolithic, multi-junction PV device having a subcell interconnection scheme that takes advantage of the n degrees of freedom available on a three dimensional device to make n independent, serially or serially and in-parallel, interconnected subcell strings. This embodiment relies on the BT-MIM concept above, but applied to n band-gap energies utilizing the filling of two-dimensional space with periodic tilings, referred to herein as nT-MIMs. Each tiling serves as a mesa shape with an even number of opposed facets. Strings of serially connected tandem subcells follow paths that pass through the pairs of facets on each tile. The shape of the tiles can be manipulated to adjust the number of subcells per unit length along an interconnected path. Note that a fuller explanation of nT-MIMs is provided in the co-pending application entitled “Voltage-Matched, Monolithic, Multi-Band-Gap Devices,” having the same inventive and ownership entities, and having been filed on the same day as the present application.

Embodiments of the present invention include voltage matching three or more stacked strings of subcells, where the subcells of each stacked layer are monolithically grown on a compliant substrate. These embodiments include voltage matching the subcell strings as well as activating the base substrate and voltage matching it in relation to the subcell strings. Tables 6-9 provide possible semiconductor materials for use in the voltage matched PV cell subcells. Also note that the present invention includes PV devices having a plurality of PV cells with three or more subcells each, where two of the subcells in each PV cell are intraconnected (current matched) with a tunnel junction, and interconnected, serially or in-parallel, to intraconnected subcells in a next PV cell. This connection of two subcells across each PV cell provides a first subcell string. The third subcell in each PV cell is serially or in-parallel interconnected to another third subcell of the next PV cell to provide a second subcell string. The two subcell strings can be voltage matched as discussed above. This concept of intraconnecting subcelis by current matching within a PV cell and interconnecting these subcells with other intraconnected subcells can be applied to four, and if applicable, higher band-gap PV cell containing devices.

It should be noted that the present invention also envisions current matching multiple PV cell subcells throughout a PV device and voltage matching a string of these to another subcell string, or to the base substrate of the device. As is apparent to one of skill in the art, any number of possible combinations of how the PV cells of the present invention can be connected is within the scope of the present invention.

Although not shown, it is recognized that the above embodiments may be readily modified to provide subcells for numerous PV cell arrangements or circuits. With the selection and use of these semiconductor and substrate materials, the present invention effectively balances the benefits of lattice-matching subcells with fabricating a device that efficiently converts an improved portion of received solar radiation into useful energy. The subcells may be utilized in a variety of electrical contact configurations, such as, the interconnection of a number of stacks of absorber layers of the present invention in a series circuit via known conductive materials and layers and standard contact methods. Further, the present invention is directed to various methods of obtaining subcells, such as, n+pp+-doping, p+nn+-doping, and other known methods of fabricating semiconductor materials to control conductivity and absorber efficiencies.

Further, the PV devices of the present invention may comprise other well-known layers or coatings to increase the total energy conversion efficiency, such as, anti-reflective coatings, stop-etch layers, a passivating window layer on the front of the absorber layer, and a passivating back surface field. For example, homojunctions and heterojunctions may be used individually or in combination to fabricate the various embodiments of the present invention.

Light Enmitting Diodes

It should be understood that the principles of fabricating monolithic, PV cells incorporating compliant substrates, and of voltage matching subcell strings from multi-subcell PV cells, can be applied to the field of light emitting diodes.

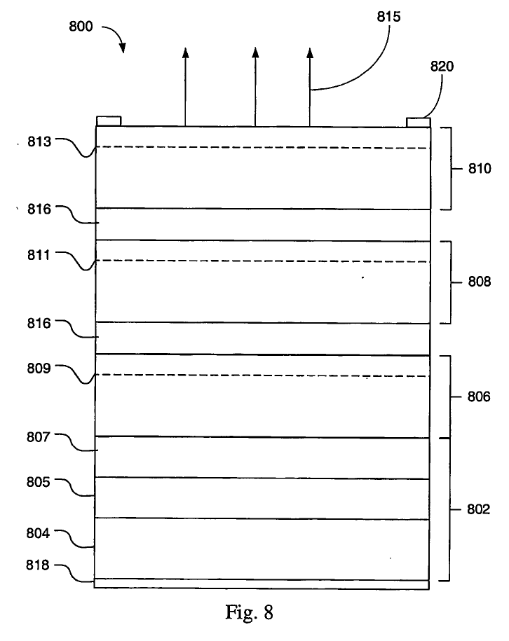

A light emitting cell of the present invention typically has three PCC layer bracketed subcells separated from each other by either an interconnection layer of material or an isolation layer of material (see FIG. 8). A light emitting diode emits light in proportion to forward current through the LEND cell. Uke PV cells, each subcell is composed of a p-type and n-type semiconductor material which form a junction. The junction acts as a barrier to the flow of electrons between the p-type and n-type materials. Only when sufficient voltage is applied to the light emitting subcell, can current flow across the barrier and electrons cross from the n-tppe material into the p-type material.

When the electrons in the n-type region have sufficient energy to cross the junction they are immediately attracted to the positive charges in the p-type region, thereby causing the electrons and positive charges to re-combine. This recombination results in the emission of electromagnetic energy in the form of a photon of light with a frequency characteristic of the semi-conductor material in the particular subcell. As such, emitted photons of light from two or more different subcells can be combined to provide a variety of different light colors.

As shown in FIG. 8, the present invention includes the fabrication of monolithic, multi-subcell light emitting cells 800 having a compliant substrate 802 (having a silicon base layer 804 silicon, dioxide intermediate layer 805 and perovskite layer 807), a first subcell 806 with active junction 809 composed of a semiconductor material having a band-gap energy consistent with the emission of red-yellow light, and a second subcell 808 with active junction 811 composed of a semiconductor material having a band-gap energy consistent with the emission of green light. The compliant substrate 802 of the present invention provides a flexible template for aligning lattice matched semiconductor materials in the red-yellow and green emission spectrum. Preferred semiconductor materials for red-yellow and green emitter colors for fabrication of several preferred embodiments are shown in Table 10.

TABLE 10
Red/Green/Blue (RGB) Light-Emitting Diode (LED) Structures

| Emitter | Emitter | Emitter Band-gaps | | |
|---|---|---|---|---|
| Color | Materials | (eV) | PCC Mat. | Lat. Con./Com. |
| Red-Yellow | AlₓGa_{y}In_{1-x-y}As_{z}P_{1-z} | 1.8-2.2 | AlₓGa_{y}In_{1-x-y}As_{z}P_{1-z} | 5.6-5.8 |
| Green | AlₓGa_{y}In_{1-x-y}As_{z}P_{1-z} | 2.2-2.4 | AlₓGa_{y}In_{1-x-y}As_{z}P_{1-z} | 5.6-5.8 |
| Blue | GaₓIn₁₋ₓN | 2.4-2.6 | AlₓGa_{y}In_{1-x-y}N | Typically grown on |
| | | | | sapphire, this device |
| | | | | would be added |
| | | | | mechanically to create the |
| | | | | Red/Green/Blue, three |
| | | | | color LED |

Within the context of Table 10, x, y, and z have values from 0 to 1, and the sum of any combination of x, y, and z in a subcell or PCC material has a value of from 0 to 1.

A third subcell 810 with an active junction 813, is fabricated from a semiconductor material having blue light emission and is mechanically stacked onto the monolithically grown red-yellow/green light emitting cell. Fabrication of the blue light emitting subcell is discussed in “InGaN Based Blue Light-emitting Diodes and Laser Diodes,” by S. Nakamura in Journal of Crystal Growth, which is incorporated herein by reference in its entirety. The combination of cells monolithically grown having red-yellow and green emitting semiconductor materials with manually attached blue emitting semiconductor material results in a white light emitting cell. Using nT-MIMs technology discussed above, the red-yellow subcells from a plurality of light emitting cells can be interconnected to give a certain voltage, the green subcells from a plurality of light emitting cells can be interconnected to give the same voltage, and the blue subcells can be interconnected to give the same voltage. Using nT-MIMs the three voltages can be substantially equalized (using series or parallel interconnections), but can also be independently tuned to adjust the hue of the white light emission 815. Also note that non-white light emitting cells (devices) can be fabricated using combinations of different semiconductor materials and BT- and nT-MIMs techniques. For example, a monolithic light emitting device can be fabricated using red-yellow and green subcells. Also note that appropriate isolation layers 816 are provided between the subcells. In an alternative embodiment, isolation layers are replaced by series connection layers and the subcells are serially connected. Where appropriate, contacts 818 and 820 can supply the required voltage.

It is understood for purposes of this disclosure, that various changes and modifications may be made to the invention that are well within the scope of the invention. Numerous other changes may be made which will readily suggest themselves to those skilled in the art and which are encompassed in the spirit of the invention disclosed herein and as defined in the appended claims.

This specification contains numerous citations to references such as patents, patent applications, and publications. Each is hereby incorporated by reference for all purposes.

What is claimed is:

1. A photovoltaic cell for converting radiant energy into electrical current and voltage, the electrical current created by charge carrier movement, the photovoltaic cell comprising:
a compliant substrate comprising:
a base layer of silicon having a layer of perovskite oxide positioned thereon and a layer of silicon oxide interposed there-between, the silicon oxide layer providing interfacial stress relief to the overlying perovskite oxide layer, allowing the compliant substrate to accommodate growth of semiconductor materials having a lattice constant from about 5.4 Å to about 5.9 Å;
a first subcell monolithically stacked on the compliant substrate, the first subcell having a junction of at least one p-type layer of semiconductor material in face-to-face contact with at least one n-type layer of semiconductor material, the first subcell having a lattice constant accommodated by the compliant substrate, and wherein the first subcell has a predetermined first band-gap energy; and
terminals attached to the photovoltaic cell to conduct current from and into the photovoltaic cell.

2. The photovoltaic cell of claim 1 further comprising:
a first passivation/confinement cladding layer interposed between the compliant substrate and the first subcell and a second passivation/confinement cladding layer positioned on the first subcell, the first and second passivation/confinement cladding layers comprising materials to minimize the interfacial recombination of carriers within the first subcell, and thereby facilitating the first subcell's current and voltage.

3. The photovoltaic cell of claim 1 wherein the perovskite oxide is strontium titanate (SrTiO₃).

4. The photovoltaic cell of claim 1 wherein the perovskite oxide is barium titanate (BaTiO₃).

5. The photovoltaic cell of claim 3 wherein the photovoltaic cell is a solar photovoltaic cell.

6. The photovoltaic cell of claim 3 wherein the photovoltaic cell is a thermophotovoltaic cell.

7. The photovoltaic cell of claim 5 wherein the first subcell is fabricated from a semiconductor material selected from a group consisting essentially of GaAs, InP, GaAsₓP₁₋ₓ, GaₓIn₁₋ₓP, GaₓIn₁₋ₓAs, GaAsₓSb₁₋ₓ, AlₓIn₁₋ₓAs, AlₓGa₁₋ₓAs, AlₓGa_{y}In_{1-x-y}P, GaₓIn₁₋ₓAs_{y}P_{1-y}, AlₓGa₁₋ₓAs_{y}Sb_{1-y}, AlₓGa_{y}In_{1-x-y}As, and GeₓSi_{1-X}, wherein x and y are values from 0 to 1 and the sum of x and y in any one semiconductor material is from 0 and 1.

8. The photovoltaic cell of claim 5 wherein the first subcell is fabricated from a semiconductor material selected from a group consisting of GaAs and InP.

9. The photovoltaic cell of claim 6 wherein the first subcell is fabricated from a semiconductor material selected from a group consisting of Ge, GeₓSi₁₋ₓ, GaₓIn₁₋ₓAs, InAsₓP₁₋ₓ, GaAsₓSb₁₋ₓ, GaₓIn₁₋ₓAs_{y}P_{1-y}, and GaₓIn₁₋ₓAs_{y}Sb_{1-y}, wherein x and y are values from 0 to 1 and the sum of x and y in any one semiconductor material is from 0 to 1.

10. The photovoltaic cell of claim 6 wherein the first subcell is fabricated from a semiconductor material selected from a group consisting of Ge.

11. The photovoltaic cell of claim 2 further comprising:
a second subcell monolithically stacked on the first subcell, the second subcell having a junction of at least one p-type layer of semiconductor material in face-to-face contact with at least one n-type layer of semiconductor material, wherein the second subcell has a lattice constant matched to the lattice constant of the first subcell and wherein the second subcell has a predetermined second band gap energy, the second band gap energy being greater than the first band gap energy; and
a first interconnection layer interposed between the second passivation/confinement cladding layer and the second subcell, the interconnection layer comprising materials that facilitate current flow between the first subcell and the second subcell.

12. The photovoltaic cell of claim 1 1 further comprising:
a third passivation/confinement cladding layer interposed between the first interconnection layer and the second subcell, and a fourth passivafion/confinement cladding layer positioned on the second subcell, wherein the third and fourth passivation/confinement cladding layers comprise materials for minimizing the interfacial recombination of carriers within the second subcell and thereby facilitating the second subcell's current and voltage.

13. The photovoltaic cell of claim 11 wherein the perovskite oxide is strontium titanate (SrTiO₃).

14. The photovoltaic cell of claim 11 wherein the perovskite oxide is barium titanate (BaTiO3).

15. The photovoltaic cell of claim 11 wherein the photovoltaic cell is a solar photovoltaic cell.

16. The photovoltaic cell of claim 12 wherein the photovoltaic cell is a thermophotovoltaic cell.

17. The photovoltaic cell of claim 15 wherein the first subcell is fabricated from GaAs and the second subcell is fabricated from GaₓIn₁₋ₓP, wherein x is from 0 to 1.

18. The photovoltaic cell of claim 15 wherein the first subcell is fabricated from GaₓIn₁₋ₓAs and the second subcell is fabricated from GaₓIn₁₋ₓP, wherein x is from 0 to 1.

19. The photovoltaic cell of claim 15 wherein the first subcell is fabricated from GaₓIn₁₋ₓAs and the second subcell is fabricated from InP, wherein x is from 0 to 1.

20. The photovoltaic cell of claim 15 wherein the first subcell is fabricated from GaₓIn₁₋ₓAs and the second subcell is fabricated from GaₓIn₁₋ₓAs_{y}P_{1-y}, wherein x and y are from 0 to 1 and the sum of x and y is from 0 and 1.

21. The photovoltaic cell of claim 16 wherein the first subcell is fabricated from Ga_{y}In_{1-y}As and the second subcell is fabricated from GaₓIn₁₋ₓAs, wherein x and y are from 0 to 1.

22. The photovoltaic cell of claim 16 wherein the first subcell is fabricated from GaᵤIn₁₋ᵤAsᵥP₁₋ᵥ and the second subcell is fabricated from GaₓIn₁₋ₓAs_{y}P_{1-y}, wherein x, y, u and v are from 0 to 1 and the sum of any combination of x, y, u and v is from 0 to 1.

23. The photovoltaic cell of claim 2 further comprising:
a second subcell monolithically stacked on the first subcell, the second subcell having a junction of at least one p-type layer of semiconductor material in face-to-face contact with at least one n-type layer of semiconductor material, wherein the second subcell has a lattice constant matched to the lattice constant of the first subcell and wherein the second subceH has a predetermined second band gap energy, the second band gap energy greater than the first band gap energy; and
a first isolation layer interposed between the second passivation/confinement cladding layer and the second subcell, the isolation layer comprising materials that prevents current flow between the first subcell and the second subcell.

24. The photovoltaic cell of claim 23 wherein the photovoltaic cell is a solar photovoltaic cell.

25. The photovoltaic cell of claim 23 wherein the photovoltaic cell is a thermophotovoltaic cell.

26. The photovoltaic cell of claim 24 wherein the first subcell is fabricated from GaAs and the second subcell is fabricated from GaₓIn₁₋ₓP, wherein x is from 0 to 1.

27. The photovoltaic cell of claim 24 wherein the first subcell is fabricated from GaₓIn₁₋ₓAs and the second subcell is fabricated from GaₓIn₁₋ₓP, wherein x is from 0 to 1.

28. The photovoltaic cell of claim 24 wherein the first subcell is fabricated from GaₓIn₁₋ₓAs and the second subcell is fabricated from InP, wherein x is from 0 to 1.

29. The photovoltaic cell of claim 24 wherein the first subcell is fabricated from GaₓIn₁₋ₓAs and the second subcell is fabricated from GaₓIn₁₋ₓAs_{y}P_{1-y}, wherein x and y are from 0 to 1 and the sum of x and y is from 0 and 1.

30. The photovoltaic cell of claim 25 wherein the first subcell is fabricated from Ga_{y}In_{1-y}As and the second subcell is fabricated from GaₓIn₁₋ₓAs, wherein x and y are from 0 to 1.

31. The photovoltaic cell of claim 25 wherein the first subcell is fabricated from GaᵤIn₁₋ᵤAsᵥP₁₋ᵥ and the second subcell is fabricated from GaₓIn₁₋ₓAs_{y}P_{1-y}, wherein x, y, u and v are from 0 to 1 and the sum of any combination of x, y, u and v is from 0 to 1.

32. The photovoltaic cell of claim 12 further comprising:
a third subcell monolithically stacked on the second subcell, the third subcell having a junction of at least one p-type layer of semiconductor material in face-to-face contact with at least one n-type layer of semiconductor material, wherein the third subcell has a lattice constant matched to the lattice constant of the second subcell and wherein the third subcell has a predetermined third band gap energy, the third band gap energy being greater than the second band gap energy; and
a second interconnection layer interposed between the fourth passivation/confinement cladding layer and the third subcell, the interconnection layer comprising materials that facilitate current flow between the second subcell and the third subcell.

33. The photovoltaic cell of claim 32 further comprising:
a fifth passivation/confinement cladding layer interposed between the second interconnection layer and the third subcell, and a sixth passivation/confinement cladding layer positioned on the third subcell, wherein the fifth and sixth passivation/confinement cladding layers comprise materials for minimizing the recombination of carriers within the third subcell and thereby facilitating the third subcell's current and voltage.

34. The photovoltaic cell of claim 32 wherein the photovoltaic cell is a solar photovoltaic cell.

35. The photovoltaic cell of claim 32 wherein the photovoltaic cell is a thermophotovoltaic cell.

36. The photovoltaic cell of claim 34 wherein the first subcell is fabricated from Ge, the second subcell is fabricated from GaAs, and the third subcell is fabricated from GaₓIn₁₋ₓP, wherein x has a value from 0 to 1.

37. The photovoltaic cell of claim 34 wherein the first subcell is fabricated from Ge_{z}Si_{1-z}, the second subcell is fabricated from GaAs_{y}P_{1-y}, and the third subcell is fabricated from GaₓIn₁₋ₓP, wherein the value of x, y, and z are from 0 to 1.

38. The photovoltaic cell of claim 34 wherein the first subcell is fabricated from Ge, the second subcell is fabricated from Ga_{y}In_{1-y}As, and the third subcell is fabricated from GaₓIn₁₋ₓP, wherein the value of x and y are from 0 to 1.

39. The photovoltaic cell of claim 35 wherein the first subcell is fabricated from Ga_{z}In_{1-z}As, the second subcell is fabricated from Ga_{y}In_{1-y}As, and the third subcell is fabricated from GaₓIn₋ₓAs, wherein the values of x, y and z are from 0 to 1.

40. The photovoltaic cell of claim 35 wherein the first subcell is fabricated from Ga_{w}In_{1-w}As_{z}P_{1-z}, the second subcell is fabricated from GaᵤIn₁₋ᵤAsᵥP₁₋ᵥ and the third subcell is fabricated from GaₓIn₁₋ₓAs_{y}P_{1-y}, wherein the values of u, v, w, x, y and z are from 0 to 1 and the sum of any combination of u, v, w, x, y and z is from 0 to 1.

41. The photovoltaic cell of claim 35 wherein the first subcell is fabricated from GaᵤIn₁₋ₓAs_{y}Sb_{1-y}, the second subcell is fabricated from InAs_{y}P_{1-y} and the third subcell is fabricated from AlₓIn₁₋ₓAs, wherein the values of u, x and y are from 0 to 1 and the sum of any combination of u, x and y is from 0 to 1.

42. The photovoltaic cell of claim 23 further comprising:
a third subcell monolithically stacked on the second subcell, the third subcell having a junction of at least one p-type layer of semiconductor material in face-to-face contact with at least one n-type layer of semiconductor material, wherein the third subcell has a lattice constant matched to the lattice constant of the second subcell and wherein the third subcell has a predetermined third band gap energy, the third band gap energy greater than the second band gap energy; and
a second isolation layer interposed between the sixth passivation/confmement cladding layer and the fourth subcell, the isolation layer comprising materials that prevents current flow between the third subcell and the fourth subcell.

43. The photovoltaic cell of claim 42 further comprising:
a fourth subcell monolithically stacked on the third subcell, the fourth subcell having a junction of at least one p-type layer of semiconductor material in face-to-face contact with at least one n-type layer of semiconductor material, wherein the fourth subcell has a lattice constant matched to the lattice constant of the third subcell and wherein the fourth subcell has a predetermined fourth band gap energy, the fourth band gap energy greater than the third band gap energy; and
a third interconnection layer interposed between the fourth passivation/confinement cladding layer and the third subcell, the interconnection layer comprising materials that facilitate current flow between the second subcell and the third subcell.

44. The photovoltaic cell of claim 43 wherein the photovoltaic cell is a solar photovoltaic cell.

45. The photovoltaic cell of claim 43 wherein the photovoltaic cell is a thermophotovoltaic cell.

46. The photovoltaic cell of claim 44 wherein the first subcell is fabricated from Ge, the second subcell is fabricated from GaAs, and the third subcell is fabricated from GaₓIn₁₋ₓP, wherein x has a value from 0 to 1.

47. The photovoltaic cell of claim 44 wherein the first subcell is fabricated from Ge_{z}Si_{1-z}, the second subcell is fabricated from GaAs_{y}P_{1-y}, and the third subcell is fabricated from GaₓIn₁₋ₓP, wherein the value of x, y, and z are from 0 to 1.

48. The photovoltaic cell of claim 44 wherein the first subcell is fabricated from Ge, the second subcell is fabricated from Ga_{y}In_{1-y}As, and the third subcell is fabricated from GaₓIn₁₋ₓP, wherein the value of x and y are from 0 to 1.

49. The photovoltaic cell of claim 45 wherein the first subcell is fabricated from Ga_{z}In_{1-z}As, the second subcell is fabricated from Ga_{y}In_{1-y}As, and the third subcell is fabricated from GaₓIn₁₋ₓAs, wherein the values of x, y and z are from 0 to 1.

50. A photovoltaic cell for converting radiant energy into electrical energy, the photovoltaic cell comprising:
a first subcell having a base layer of silicon, an intermediate layer of silicon oxide, a top layer of perovskite oxide, the base layer of silicon having a junction of at least one p-type region in face-to-face contact with at least one n-type region therein and having a first band-gap energy, the intermediate layer of silicon oxide electrically isolating the base layer of silicon;
a second subcell monolithically stacked on the compliant substrate composed of a semiconductor material having a junction of at least one p-type region in face-to-face contact with at least one n-type region therein and having a second band-gap energy, the second band-gap energy greater than the first band-gap energy; and
terminals attached to the photovoltaic cell to conduct current from and into the photovoltaic cell.

51. The photovoltaic cell of claim 50 wherein the photovoltaic cell is a solar photovoltaic cell.

52. The photovoltaic cell of claim 50 wherein the photovoltaic cell is a thermophotovoltaic cell.

53. The photovoltaic cell of claim 51 wherein the subcell is fabricated from a semiconductor material selected from a group consisting of GaAs, InP, GaₓIn₁₋ₓP, GaAsₓP₁₋ₓ, AlₓIn₁₋ₓAs, AlₓIn₁₋ₓAs, AlₓGa₁₋ₓAs, AlₓGa_{y}In_{1-x-y}, GaₓIn₁₋ₓAs_{y}P_{1-y}, AlₓGa_{1-y}As_{y}Sb_{1-y}, AlₓGa_{y}In_{1-x-y}As, wherein the values of x and y are from 0 to 1 and the sum of any combination of x and y is from 0 to 1.

54. The photovoltaic cell of claim 51 wherein the second subcell is fabricated from a semiconductor material selected from a group consisting of GaAs and InP.

55. A photovoltaic device for converting radiant energy into electrical energy, the photovoltaic device comprising:
an array of photovoltaic cells, each photovoltaic cell comprising:
a first subcell having a base layer of silicon, an intermediate layer of silicon oxide, a top layer of perovskite oxide, the base layer of silicon having a junction of at least one p-type region in face-to-face contact with at least one n-type region therein and having a first band-gap energy, the intermediate layer of silicon oxide electrically isolating the base layer of silicon;
a second subcell monolithically stacked on the compliant substrate composed of a semiconductor material having a junction of at least one p-type region in face-to-face contact with at least one n-type region therein and having a second band-gap energy, the second band-gap energy greater than the first band-gap energy; and
a first subcell string formed by serially interconnecting at least one first subcell from the array of photovoltaic cells to another first subcell from the array of photovoltaic cells; and
a second subcell string formed by serially interconnecting at least one second subcell from the array of photovoltaic cells to another second subcell from the array of photovoltaic cells wherein the number of subcells in the first subcell string is adjusted to provide a first voltage and the number of subcells in the second subcell string is adjusted to provide a second voltage, the first and second voltages being substantially matched.

56. The photovoltaic device of claim 55 wherein the photovoltaic device is a solar photovoltaic device.

57. The photovoltaic device of claim 55 wherein the photovoltaic device is a thermophotovoltaic device.

58. The photovoltaic device of claim 56 wherein the second subcell is fabricated from a semiconductor material selected from a group consisting of GaAs, InP, GaₓIn₁₋ₓP, GaAsₓP₁₋ₓ, AlₓIn₁₋ₓAs, AlₓIn₁₋ₓAs, AlₓGa₁₋ₓAs, AlₓGa_{y}In_{1-x-y}, GaₓIn₁₋ₓAs_{y}P_{1-y}, AlₓGa₁₋ₓAs_{y}Sb_{1-y}, AlₓGa_{y}In_{1-y}As, wherein the values of x and y are from 0 to 1 and the sum of any combination of x and y is from 0 to 1.

59. The photovoltaic device of claim 56 wherein the second subcell is fabricated from a semiconductor material selected from a group consisting of GaAs and InP.

60. The photovoltaic device of claim 55 wherein the photovoltaic cell further comprises a third subcell monolithically stacked on the second subcell, the third subcell composed of a semiconductor material having a junction of at least one p-type region in face-to-face contact with at least one n-type region therein, and having a third band-gap energy, the third band-gap energy greater than the second band-gap energy, and wherein the photovoltaic device further comprises a third subcell string formed by serially interconnecting at least one third subcell from the array of photovoltaic cells to another third subcell from the array of photovoltaic cells, wherein the number of subcells in the third subcell string is adjusted to provide a third voltage, the third voltage being substantially matched to the first and second voltages.

61. The photovoltaic device of claim 60 wherein the photovoltaic device is a solar photovoltaic device.

62. The photovoltaic device of claim 60 wherein the photovoltaic device is a thermophotovoltaic device.

63. The photovoltaic device of claim 61 wherein the second subcell is fabricated from GaAs and the third subcell is fabricated from GaₓIn₁₋ₓP, wherein x has a value of from 0 to 1.

64. The photovoltaic device of claim 61 wherein the second subcell is fabricated from GaAsᵥP₁₋ᵥ and the third subcell is fabricated from GaₓIn₁₋ₓP, wherein x and v have a value of from 0 to 1.

65. The photovoltaic device of claim 61 wherein the second subcell is fabricated from GaAs_{y}P_{z}N_{1-y-z} and the third subcell is fabricated from GaₓIn₁₋ₓP, wherein x, y, and z have values of from 0 to 1 and the sum of any combination of y and z is from 0 to 1.

66. The photovoltaic device of claim 61 wherein the second subcell is fabricated from GaₓIn₁₋ₓP and the third subcell is fabricated from AlₓIn₁₋ₓP, wherein x has a value of from 0 to 1.

67. The photovoltaic device of claim 61 wherein the second subcell is fabricated from GaAs and the third subcell is fabricated from AlₓGa₁₋ₓAs, wherein the value of x is from 0 to 1.

68. A photovoltaic device for converting radiant energy into electrical energy, the photovoltaic device comprising:
an array of photovoltaic cells, each photovoltaic cell comprising:
a compliant substrate having a base layer of silicon, an intermediate layer of silicon oxide, a top layer of perovskite oxide, the compliant substrate accommodating monolithic growth of semiconductor materials having a lattice constant from about 5.4 Å to about 5.9 Å;
a first subcell monolithically stacked on the compliant substrate, the first subcell composed of a semiconductor material having a junction of at least one p-type region in face-to-face contact with at least one n-type region therein and having a first band-gap energy; and
a second subcell monolithically stacked on the first subcell, the second subcell composed of a semiconductor material having a junction of at least one p-type region in face-to-face contact with at least one n-type region therein and having a second band-gap energy, the second band-gap energy greater than the first band-gap energy;
a first subcell string formed by serially interconnecting at least one first subcell from the array of photovoltaic cells to another first subcell from the array of photovoltaic cells; and a second subcell string formed by serially interconnecting at least one second subcell from the array of photovoltaic cells to another second subcell from the array of photovoltaic cells
wherein the number of subcells in the first subcell string is adjusted to provide a first voltage and the number of subcells in the second subcell string is adjusted to provide a second voltage, the first and second voltages being substantially matched.

69. The photovoltaic device of claim 68 wherein the photovoltaic device is a solar photovoltaic device.

70. The photovoltaic device of claim 68 wherein the photovoltaic device is a thermophotovoltaic device.

71. The photovoltaic device of claim 69 wherein the first subcell is fabricated from GaAs and the second subcell is fabricated from GaₓIn₁₋ₓP, wherein the value of x is from 0 to 1.

72. The photovoltaic device of claim 69 wherein the first subcell is fabricated from GaₓIn₁₋ₓAs and the second subcell is fabricated from GaₓIn₁₋ₓP, wherein the value of x is from 0 to 1.

73. The photovoltaic device of claim 69 wherein the first subcell is fabricated from GaₓIn₁₋ₓAs and the second subcell is fabricated from InP, wherein the value of x is from 0 to 1.

74. The photovoltaic device of claim 70 wherein the first subcell is fabricated from Ga_{y}In_{1-y}As and the second subcell is fabricated from GaₓIn₁₋ₓAs, wherein the values of x and y are from 0 to 1.

75. The photovoltaic device of claim 70 wherein the first subcell is fabricated from Ga_{y}In_{1-y}As and the second subcell is fabricated from InAsₓP₁₋ₓ, wherein the values of x and y are from 0 to 1.

76. A light emitting device for converting electrical energy into light, the light emitting device comprising:
an array of light emitting cells, each light emitting cell comprising:
a compliant substrate having a base layer of silicon, an intermediate layer of silicon dioxide, a top layer of perevskite oxide, the compliant substrate accommodating monolithic growth of semiconductor materials having a lattice constant from about 5.4 Å to about 5.9 Å;
a first subcell monolithically stacked on the compliant substrate, the first subcell composed of a semiconductor material having a junction of at least one p-type region in face-to-face contact with at least one n-type region therein, the semiconductor material having a lattice constant accommodated by the compliant substrate, the semiconductor material having a first band-gap energy characteristic of the emission of red light in response to sufficient voltage;
a second subcell monolithically stacked on the first subcell, the second subcell composed of a semiconductor material having a junction of at least one p-type region in face-to-face contact with at least one n-type region therein, the semiconductor material lattice matched to the first subcell, the semiconductor material having a second band-gap energy characteristic of the emission of green light in response to sufficient voltage; and
a third subcell mechanically stacked on the second subcell, the third subcell composed of a semiconductor material having a junction of at least one p-type region in face-to-face contact with at least one n-type region therein, the semiconductor material having a third band-gap energy characteristic of the emission of blue light in response to sufficient voltage;
a first subcell string formed by serially interconnecting at least one first subcell from the array of light emitting cells to another first subcell from the array of light emitting cells;
a second subcell string formed by serially interconnecting at least one second subcell from the array of light emitting cells to another second subcell from the array of light emitting cells; and
a third subcell string formed by serially interconnecting at least one third subcell from the array of light emitting cells to another third subcell from the array of light emitting cells;
wherein the first subcell string, second subcell string and third subcell string are independently tuned to produce a target hue of light.

77. The photovoltaic device of claim 76 wherein the first subcell is fabricated from AlₓGa_{y}In_{1-x-y}As_{z}, the second subcell is fabricated from AlₓGa_{y}In_{1-x-y}As_{z}P_{1-z}, and the third subcell is fabricated from GaₓIn₁₋ₓN, wherein the values of x, y and z are from 0 to 1 and the sum of any combination of x, y and z is from 0 to 1.
